(19) United States
(12) Patent Application Publication
(10) Pub. No.: US 2009/0218671 A1
(43) Pub. Date: Sep. 3, 2009

(54) SEMICONDUCTOR DEVICE AND METHOD OF FABRICATING THE SAME

(76) Inventor: Kimihito Kuwabara, Kyoto (JP)

Correspondence Address: MCDERMOTT WILL & EMERY LLP, 600 13TH STREET, NW, WASHINGTON, DC, 20005-3096, US

(21) Appl. No.: 12/395,991

(22) Filed: Mar. 2, 2009

(30) Foreign Application Priority Data
Mar. 3, 2008 (JP) 2008-052361
Jan. 14, 2009 (JP) 2009-005856

(51) Int. Cl. H01L 25/00; H01L 21/48

(52) U.S. Cl. 257/686; 438/109; 257/777; 257/738; 257/E21.499; 257/E25.001

(57) ABSTRACT

In a semiconductor device of the present invention, semiconductor chips are stacked in multi-layers. Each of the semiconductor chip includes: through vias extending through a top main surface thereof to a bottom surface opposite to the top main surface; a circuit element surface formed on the top main surface; pads arranged on the circuit element surface; bumps formed on the pads; and via pads, formed on the bottom surface thereof, to which the bumps of its upper semiconductor chip are joined, and positions at which the bumps of each of the semiconductor chips are respectively arranged are different from those at which the bumps of its upper semiconductor chip are arranged.

### BACKGROUND OF THE INVENTION

1. Field of the Invention

The present invention relates to a semiconductor device, and more particularly to a semiconductor device having a package structure in which a plurality of semiconductor chips are three-dimensionally stacked and a method of fabricating the same.

2. Description of the Background Art

In recent years, for further reducing the thickness, size and weight of electrical apparatuses (cellular phones and the like), a package of the semiconductor device has been shifted from a peripheral lead type package to a Ball Grid Array (BGA) type package and further to a chip size package (CSP). The CSP technology provides a semiconductor package (semiconductor device) having an area substantially equivalent to that of each individual chip cutout from a wafer. Furthermore, for realizing the further reduced thickness, size and weight of a semiconductor package, a wafer level chip size package (WLCSP) has been proposed instead of a bare chip and has become widely used recently, since the bare chip is not easy to use when mounting the chip to an electrical apparatus. The WLCSP is a technique in which rewiring and resin sealing are performed on a wafer, and then the wafer is divided into individual semiconductor chips.

Furthermore, in order to satisfy the need for enhanced speed of signals in electrical circuits and increased scale of the electrical circuits, research and development for SiP (System-in-Package) has been actively conducted. In a typical example of SiP, a plurality of semiconductor chips are stacked in one package. For example, Japanese Patent Publication No. 3917484 discloses a three-dimensionally stacked semiconductor device having high-density semiconductor chips mounted thereon by stacking multiple semiconductor chips so as to be electrically connected to each other. Hereinafter, a semiconductor device according to the prior art will be described with reference to the drawings.

FIG. 28 is a cross-sectional view of a semiconductor device 1000 according to the prior art. In FIG. 28, the semiconductor device 1000 has a package structure in which first to fourth semiconductor chips 11 to 14 are stacked onto an interposer substrate 1. In the first to fourth semiconductor chips 11 to 14, reference numerals are sequentially assigned starting from the bottom semiconductor chip closest to the interposer substrate 1, to the top.

On a top surface of the interposer substrate 1 (i.e., a surface on the side of the first semiconductor chip 11), substrate lands 2 are disposed by means of etching performed on planting or copper. On a bottom surface of the interposer substrate 1 (i.e., a surface on the side opposite to the side of the first semiconductor chip 11), soldering lands 3 are disposed. The substrate lands 2 are electrically connected to the soldering lands 3 via conductors such as vias or wirings which are formed in the interior of the interposer substrate 1. In the case where the semiconductor device 1000 is connected to a circuit board of an electrical apparatus, solder balls 4 respectively formed on the soldering lands 3 are used to connect the semiconductor device and the circuit board.

Furthermore, FIG. 29 is an enlarged view of a portion 1100 in which the semiconductor chips included in the semiconductor device 1000 shown in FIG. 28 are joined to each other. On top main surfaces of the first to fourth semiconductor chips 11 to 14 (i.e., surfaces on the side of the interposer substrate 1), first to fourth circuit element surfaces 21 to 24 are formed, respectively. Furthermore, in order to conduct electricity between each of the top main surfaces of the first to third semiconductor chips 11 to 13 and its bottom surface which is opposite thereto (i.e., a surface opposite to the surface on the side of the interposer substrate 1), first to third through vias 31 to 33 are respectively formed at one or more locations within the first to third semiconductor chips 11 to 13, respectively. FIG. 28 illustrates an example where each of the first to third through vias 31 to 33 is formed at six locations. The first to third through vias 31 to 33 formed within the respective semiconductor chips are located at the same position. At the position where the first to third through vias 31 to 33 are formed, first to fourth electrode pads 41 to 44 are disposed on the first to fourth circuit element surfaces 21 to 24, respectively, and first to third via pads 61 to 63 are disposed on bottom surfaces of the first to third semiconductor chips 11 to 13, respectively.

Note that the electric wiring is formed on the bottom surface of each of the first to third semiconductor chips 11 to 13, and the first to third via pads 61 to 63 are terminal portions. Furthermore, first to fourth bumps 51 to 54 are formed on the first to fourth electrode pads 41 to 44 as protruding electrodes of the first to fourth semiconductor chips 11 to 14, respectively. The first to fourth bumps 51 to 54 are electrode terminals for electrically connecting circuit elements of the respective first to fourth semiconductor chips 11 to 14 to the exterior thereof.

As described above, the first semiconductor chip 11 is electrically connected to the interposer substrate 1 by bonding the first bump 51 to the substrate land 2 of the interposer substrate 1. Similarly, the second semiconductor chip 12 is electrically connected to the first semiconductor chip 11 by bonding the second bump 52 to the first via pad 61 of the first semiconductor chip 11. Similarly, the third semiconductor chip 13 is electrically connected to the second semiconductor chip 12 by bonding the third bump 53 to the second via pad 62 of the second semiconductor chip 12. Similarly, the fourth semiconductor chip 14 is electrically connected to the third semiconductor chip 13 by bonding the fourth bump 54 to the third via pad 63 of the semiconductor chip 13.

More specifically, the first bump 51, acting as an electrode of the top main surface of the first semiconductor chip 11, is connected to the substrate land 2 of the interposer substrate 1, and the second to fourth bumps 52 to 54, acting as electrodes of the top main surfaces of the second to fourth semiconductor chips 12 to 14, are connected to the first to third via pads 61 to 63 formed on the bottom surfaces of the first to third semiconductor chips 11 to 13, respectively, by using the flip-chip method. Furthermore, in order to secure reliability of the flip-chip connection, first to fourth sealing resins 71 to 74 are formed between the interposer substrate 1 and the first semiconductor chip 11, between the first semiconductor chip 11 and the second semiconductor chip 12, between the second semiconductor chip 12 and the third semiconductor chip 13, and between the third semiconductor chip 13 and the fourth semiconductor chip 14, respectively. The first to fourth sealing resins 71 to 74 are injected into a gap between the interposer substrate 1 and the first semiconductor chip 11, a gap between the first semiconductor chip 11 and the second semiconductor chip 12, a gap between the second semiconductor chip 12 and the third semiconductor chip 13, and a gap between the third semiconductor chip 13 and the fourth semiconductor chip 14, respectively, all of the semiconductor chips 11 to 14 being joined to each other via the first to fourth bumps 51 to 54. The injected first to fourth sealing resins 71 to 74 are cured with heat and shrink. As such, the semiconductor device 1000 according to the prior art realizes a three-dimensional stacked package structure.

As described above, in the case where the semiconductor chips are connected to each other, the sealing resins are provided for the purpose of suppressing divergence of a soldering portion and a chip diffusion process layer, thereby improving the reliability. However, due to a difference between a thermal expansion coefficient of each semiconductor chip and a thermal expansion coefficient of sealing resin injected between semiconductor chips, a distortion or a crack generated in the semiconductor chip has been an issue. Note that this problem is not so much concerned in the flip-chip mounting of a single semiconductor chip since the thickness thereof is sufficient enough to have stiffness. However, this problem is of great concern in the flip-chip mounting of a semiconductor chip having a three-dimensional stacked structure. Hereinafter, this problem will be described in detail.

FIG. 30 is a diagram illustrating a state where in a semiconductor device 1200 formed by a single semiconductor chip, the semiconductor chip is deformed. In the semiconductor device 1200, the semiconductor chip 11 is connected onto the interposer substrate 1 by using the flip-chip method. The semiconductor device 1200 is composed of only the interposer substrate 1 and the first semiconductor chip 11 among the components included in the semiconductor device 1000. Therefore, any components included in the semiconductor device 1200 as those shown in FIGS. 28 and 29 will be denoted as the same reference numerals, and will not be further described below.

For securing the reliability of a flip-chip connection between the interposer substrate 1 and the semiconductor chip 11, the sealing resin 71 is injected into a gap therebetween. With its hardening shrinkage force, the sealing resin 71 consistently pulls the semiconductor chip 11 stacked thereon toward the interposer substrate 1. This force produces an effect to prevent a joined portion of the bump 51 to which the interposer substrate 1 is bonded and also a joined portion of the bump 51 to which the semiconductor chip 11 is bonded from becoming separated from the bump 51. Unfortunately, however, the semiconductor chip 11 is to be deformed in an area between the bump 51 which is made of Au, as a supporting point, and another bump 51 adjacent thereto (warpage displacement shown in FIG. 30).

Next, a semiconductor device in which semiconductor chips are stacked in multi-layers will be described. FIG. 31 is a diagram illustrating a state where in a semiconductor device 1300 in which semiconductor chips are stacked in multi-layers, the semiconductor chips are deformed. In the semiconductor device 1300, the second semiconductor chip 12 having the same structure as the semiconductor chip 11 is connected onto the semiconductor chip 11 of the semiconductor device 1200 shown in FIG. 30 by using the flip-chip method. The semiconductor device 1300 is composed of only the interposer substrate 1, the first semiconductor chip 11 and the second semiconductor chip 12 among the components included in the semiconductor device 1000. Therefore, any components included in the semiconductor device 1300 as those shown in FIGS. 28 and 29 will be denoted as the same reference numerals, and will not be further described below.

With its hardening shrinkage force, the first sealing resin 71 consistently pulls the first semiconductor chip 11 stacked thereon toward the interposer substrate 1. Furthermore, with its hardening shrinkage force, the second sealing resin 72 consistently pulls the second semiconductor chip 12 stacked thereon toward the first semiconductor chip 11. As shown in FIG. 31, in the semiconductor device 1300, two semiconductor chips are stacked in layers. Therefore, the deformation of the second semiconductor chip 12 becomes cumulatively greater than that of the first semiconductor chip 11 (warpage displacement as shown in FIG. 31). Note that in this example, two semiconductor chips are stacked in layers. However, in the case where three or more semiconductor chips are stacked in layers, the closer to the top a semiconductor chip is disposed, the greater the deformation thereof becomes. This is because in the conventional semiconductor device 1000 shown in FIG. 28, the through via, the electrode pad and the bump are disposed at the same position in each of the semiconductor chips which are stacked in multi-layers. Thus, the greatest deformation of the respective semiconductor chips occur at the same position at all times, and the greater the number of the semiconductor chips to be stacked, the more cumulatively the deformation increases.

Furthermore, the semiconductor device itself is required to be as thin as (to have the same mounting height as) the semiconductor device formed by a single semiconductor chip. Thus, the semiconductor device formed by multi-layered semiconductor chips is designed to be thinner. In the prior art as described above, the thickness of the semiconductor device can be reduced after packaging and soldering mounting. Thus, the thinning processing is performed on a wafer or a semiconductor chip. Conventionally, the thickness of a semiconductor chip is from 300 to 400 μm. Whereas, in recent years, the thickness of a multi-layered semiconductor chip is less than or equal to 150 μm even down to several tens of μm. If such a technology for reduction in the thickness of a semiconductor chip is utilized to reduce the thickness of a semiconductor chip to a value equal to or less than 100 to 200 μm, even if the silicon chip has elasticity of 130 to 180 Gpa which is greater than or equal to metal, the stiffness of the entire chip becomes low.

As such, in a semiconductor device formed by multi-layered semiconductor chips, when the deformation of each semiconductor chip becomes greater, stress is more concentrated on the root of a bump electrode. Furthermore, if the stiffness of the entire semiconductor chips is reduced as each semiconductor chip becomes thinner, the semiconductor device may not be completely damaged, but it is likely to generate a crack in each semiconductor chip or to have a harmful effect on a transistor formed on a circuit element surface of each semiconductor chip, thereby resulting in the characteristic variation.

In order to prevent such deformation of the semiconductor chips from being generated, Japanese Laid-Open Patent Publication No. 2004-281880 discloses that resin balls, as supporting balls, are disposed at areas where each semiconductor chip is greatly deformed, so as to be sandwiched between the semiconductor chips stacked in multi-layers. FIG. 32 is a diagram illustrating a semiconductor device 1400 in which a resin ball is disposed in an area where the semiconductor chips are greatly deformed. In the semiconductor device 1400, the resin balls are disposed between the first semiconductor chip 11 and the second semiconductor chip 12, thereby reducing the deformation of the second semiconductor chip 12 included in the semiconductor device 1300 shown in FIG. 31. Therefore, the stress which is concentrated on the root of the bump electrode of the second semiconductor chip 12 included in the semiconductor device 1300 is accordingly reduced, thereby preventing a crack from being generated in each semiconductor chip and thus it is less likely to vary the characteristic of a transistor or the like formed on the circuit element surface.

However, as described above, even in the case where the resin balls, as supporting balls, are disposed between the semiconductor chips stacked in multi-layers in order to reduce the deformation of each semiconductor chip due to the shrinkage of sealing resin, the pitch of the bump electrodes is restricted to be narrower, and thus the number of bumps is to be limited accordingly. Furthermore, by providing the resin balls, the filling property of sealing resin is hampered. As a result, the reliability of connections of the semiconductor chips stacked in multi-layers is deteriorated.

### SUMMARY OF THE INVENTION

Therefore, an object of the present invention is to provide a semiconductor device capable of preventing a crack caused by stress concentrated on one position from being generated by reducing the deformation of semiconductor chips due to the shrinkage of sealing resin, even if each semiconductor chip to be stacked on the semiconductor device is designed to be thinner, capable of realizing a high-density circuit in which a great number of electrodes are connected at narrow pitches while suppressing characteristic variation of semiconductor components formed on a circuit element surface, and capable of having a high reliability of portions in which the semiconductor chips stacked in layers are joined to each other by high-quality filling of the portions with sealing resin.

In order to attain the object mentioned above, in a semiconductor device in which at least n (n is an integer greater than or equal to 2) semiconductor chips, which are connected to each other via bumps, are arranged in a stacked layer structure of n layers, and each gap between the semiconductor chips is sealed with sealing resin, an i-th (i is an integer from 1 to n−1) semiconductor chip includes: through vias extending through a top main surface of the i-th semiconductor chip to a bottom surface opposite to the top main surface; a circuit element surface formed on the top main surface; pads arranged on the circuit element surface; bumps respectively formed on the pads; and via pads, to which the bumps of an (i+1)th semiconductor chip are respectively joined, which are disposed on the bottom surface of the i-th semiconductor chip, and an n-th semiconductor chip includes: a circuit element surface formed on a top main surface of the n-th semiconductor chip; pads arranged on the circuit element surface; and the bumps formed on the at least one pad, and each of the bumps of the i-th semiconductor chip is arranged at a position different from a position at which each of the bumps of the (i+1)th semiconductor chip is arranged.

It is preferable that the bumps are arranged on a top main surface of each of the semiconductor chips, and each of the bumps of the (i+1) th semiconductor chip is electrically connected to any of the bumps of the i-th semiconductor chip through each of the through vias.

Furthermore, it is preferable that the bumps are arranged in a matrix so as to be spaced at regular intervals on an entirety of the top main surface of each of the semiconductor chips, and each of the bumps of the (i+1)th semiconductor chip is at least arranged at a position extending vertically upward from a position of gravity center of a minimum rectangle formed by four bumps among the bumps of the i-th semiconductor chip. Still furthermore, it is preferable that a same number of bumps are arranged on each of the semiconductor chips.

Or, it is preferable that the bumps are arranged along the periphery of only two edges of each of the semiconductor chips.

Or, it is preferable that the bumps are arranged along the periphery of all four edges of each of the semiconductor chips.

It is preferable that the bumps are made of metal.

Furthermore, it is preferable that the bumps are solder balls or gold electrodes.

It is preferable that a thickness of each of the semiconductor chips is from 0.01 mm to 0.15 mm.

It is preferable that each of the bumps is formed on the circuit element surface and arranged at a position at which each of the through vias is formed.

Furthermore, it is preferable that each of the bumps is formed on the circuit element surface and arranged at a position shifted from a position at which each of the through vias is formed.

It is preferable that the periphery of each of the bumps is covered with a resin layer different from the sealing resin.

Furthermore, it is preferable that a curing shrinkage rate of the resin layer covering the periphery of each of the bumps is lower than that of the sealing resin.

Still furthermore, it is preferable that a thermal expansion coefficient of the resin layer covering the periphery of each of the bumps is lower than that of the sealing resin.

It is preferable that the semiconductor device further comprises an interposer substrate, which includes an external power source terminal, disposed below the semiconductor chips arranged in a stacked layer structure of n layers, wherein each of the bumps of the first semiconductor chip is joined to a substrate land formed on the interposer substrate.

Furthermore, it is preferable that at least one of the semiconductor chips stacked on the interposer substrate is connected to the interposer substrate by a conductive wire, or the n-th semiconductor chip is connected to the interposer substrate by a conductive wire.

In order to attain the object mentioned above, a first aspect of a method of fabricating a semiconductor device according to the present invention is a fabrication method in which at least n (n is an integer greater than or equal to 2) semiconductor chips, which are connected to each other via bumps, are arranged in a stacked layer structure of n layers, and each gap between the semiconductor chips is sealed with sealing resin, the fabrication method comprising the steps of: stacking i (i is an integer from 1 to n−1) semiconductor chips successively from a first layer; and stacking thereon an n-th semiconductor chip, wherein the step of stacking an i-th semiconductor chip includes the steps of: forming through vias extending through a top main surface of the i-th semiconductor chip to a bottom surface opposite to the top main surface; forming a circuit element surface on the top main surface of the i-th semiconductor chip; arranging pads on the circuit element surface; forming the bumps on the pads, respectively; disposing via pads, to which the bumps of an (i+1)th semiconductor chip are respectively joined, on the bottom surface of the i-th semiconductor chip, stacking the i-th semiconductor chip on the semiconductor device in which the semiconductor chips are arranged in a stacked layer structure of (i−1) layers; and filling a portion in which the i-th semiconductor chip is joined to the (i−1)th semiconductor chip with the sealing resin, and the step of further stacking the n-th semiconductor chip includes the steps of: forming a circuit element surface on a top main surface of the n-th semiconductor chip; arranging pads on the circuit element surface; and forming the bumps on the pads, respectively, stacking the n-th semiconductor chip on the semiconductor device in which the semiconductor chips are arranged in a stacked layer structure of (n−1) layers; and filling a portion in which the n-th semiconductor chip is joined to an (n−1)th semiconductor chip with the sealing resin, and each of the bumps of the i-th semiconductor chip is arranged at a position different from a position at which each of the bumps of an (i+1)th semiconductor chip is arranged.

In order to attain the object mentioned above, a second aspect of the method of fabricating the semiconductor device according to the present invention is a fabrication method of a semiconductor device in which at least n (n is an integer greater than or equal to 2) semiconductor chips, which are connected to each other via bumps, are arranged in a stacked layer structure of n layers, and each gap between the semiconductor chips is sealed with sealing resin, the fabrication method comprising the steps of: stacking i (i is an integer from 1 to n−1) semiconductor chips successively from a first layer; and stacking thereon an n-th semiconductor chip, wherein the step of stacking an i-th semiconductor chip includes the steps of: forming through vias extending through a top main surface of the i-th semiconductor chip to a bottom surface opposite to the top main surface; forming a circuit element surface on the top main surface of the i-th semiconductor chip; arranging at least one pad on the circuit element surface; arranging via pads on the bottom surface of the i-th semiconductor chip; stacking the i-th semiconductor chip on the semiconductor device in which the semiconductor chips are arranged in a stacked layer structure of (i−1) layers; filling a portion in which the i-th semiconductor chip is joined to the (i−1)th semiconductor chip with the sealing resin; forming the bumps of the (i+1)th semiconductor chip on the via pads formed on the circuit element surface of the i-th semiconductor chip; and arranging via pads to which the bumps of the (i+1)th semiconductor chip are respectively joined, and the step of stacking the n-th semiconductor chip includes the steps of: forming a circuit element surface on a top main surface of the n-th semiconductor chip; arranging pads on the circuit element surface; stacking the n-th semiconductor chip on the semiconductor device in which the semiconductor chips are arranged in a stacked layer structure of (n−1) layers; and filling a portion in which the n-th semiconductor chip is joined to an (n−1)th semiconductor chip with the sealing resin, and each of the bumps of the i-th semiconductor chip is arranged at a position different from a position at which each of the bumps of the (i+1)th semiconductor chip is arranged.

It is preferable that the step of stacking the i-th semiconductor chip on the semiconductor device in which the semiconductor chips are arranged in a stacked layer structure of (i−1) layers and the step of stacking the n-th semiconductor chip on the semiconductor device in which the semiconductor chips are arranged in a stacked layer structure of (n−1) layers further include a step of: forming, around the periphery of each of the bumps, a resin layer different from the sealing resin.

Furthermore, it is preferable that the step of forming, around the periphery of each of the bumps, the resin layer different from the sealing resin is executed by using a transfer method in which the bumps are pressed against the resin layer, or by using a screen printing method.

As described above, according to the semiconductor device of the present invention, it becomes possible to prevent a crack caused by stress concentrated on one position from being generated by reducing the deformation of semiconductor chips due to the shrinkage of sealing resin even if each semiconductor chip to be stacked on the semiconductor device is designed to be thinner, and to have a high-density circuit in which a great number of electrodes are connected at narrow pitches while suppressing characteristic variation of semiconductor components formed on a circuit element surface, and to realize a high reliability of portions in which the semiconductor chips stacked in layers are joined to each other by high-quality filling of the portions with sealing resin.

According to the semiconductor device of the present invention, it becomes possible to realize a package having the size of a chip in which ultra-thin semiconductor chips are stacked. Furthermore, in each semiconductor chip on which circuit elements are formed by an advanced micromachining process, it becomes possible to reduce deformation of each semiconductor chip as well as stress concentrated on each semiconductor chip and characteristic variation caused by the stress, while maintaining narrow pitches of bumps. Therefore, the further miniaturization and higher density of the semiconductor chip can be realized. Thus, the present invention is particularly useful to achieve higher density of not only cellular phones and electrical apparatuses which are required to be smaller and thinner but also stationary electrical apparatuses.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a diagram illustrating a semiconductor device 100 according a first embodiment of the present invention;

FIG. 2 is an enlarged view illustrating the detailed structure of a portion in which an interposer substrate 1, a first semiconductor chip 11 and a second semiconductor chip 12 included in the semiconductor device 100 shown in FIG. 1 are joined to each other;

FIG. 3 is a diagram illustrating a semiconductor device 101 according to the first embodiment of the present invention;

FIG. 4 is a diagram illustrating a semiconductor device 102 according to the first embodiment of the present invention;

FIG. 5 is a diagram illustrating a semiconductor device 103 according to the first embodiment of the present invention;

FIG. 6 is a diagram illustrating a semiconductor device 104 according to the first embodiment of the present invention;

FIG. 7 is a diagram illustrating a semiconductor device 105 according to the first embodiment of the present invention;

FIG. 8 is a diagram illustrating a semiconductor device 200 according to a second embodiment of the present invention;

FIG. 9 is an enlarged view illustrating the detailed structure of a portion in which the interposer substrate 1, the first semiconductor chip 11 and the second semiconductor chip 12 included in the semiconductor device 200 shown in FIG. 8 are joined to each other;

FIG. 10 is a diagram illustrating a semiconductor device 201 according to the second embodiment of the present invention;

FIG. 11 is a diagram illustrating a semiconductor device 300 according to a third embodiment of the present invention;

FIG. 12 is an enlarged view illustrating the detailed structure of a portion in which the interposer substrate 1, the first semiconductor chip 11 and the second semiconductor chip 12 included in the semiconductor device 300 shown in FIG. 11 are joined to each other;

FIG. 13 is an enlarged view illustrating an example of a portion in which adjacent semiconductor chips of the semiconductor device according to the first to third embodiments of the present invention are joined to each other;

FIG. 14 is an enlarged view illustrating an example of a portion in which adjacent semiconductor chips of the semiconductor device according to the first to third embodiments of the present invention are joined to each other;

FIG. 15 is an enlarged view illustrating an example of a portion in which adjacent semiconductor chips of the semiconductor device according to the first to third embodiments of the present invention are joined to each other;

FIG. 16 is a diagram illustrating an example of a bump arrangement of each of the semiconductor chips included in the semiconductor device according to the first to third embodiments of the present invention;

FIG. 17 is a diagram illustrating an example of a bump arrangement of each of the semiconductor chips included in the semiconductor device according to the first to third embodiments of the present invention;

FIG. 18 is a diagram illustrating an example of a bump arrangement of each of the semiconductor chips included in the semiconductor device according to the first to third embodiments of the present invention;

FIG. 19 is a diagram illustrating an example of a bump arrangement of each of the semiconductor chips included in the semiconductor device according to the first to third embodiments of the present invention;

FIG. 20 is a diagram illustrating an example of a bump arrangement of each of the semiconductor chips included in the semiconductor device according to the first to third embodiments of the present invention;

FIG. 21 is a diagram illustrating an example of a bump arrangement of each of the semiconductor chips included in the semiconductor device according to the first to third embodiments of the present invention;

FIG. 22A is a diagram illustrating a wafer 10 of the semiconductor device according to a sixth embodiment of the present invention;

FIG. 22B is a diagram illustrating a cross section of the wafer 10 of the semiconductor device according to the sixth embodiment of the present invention;

FIG. 22C is a diagram illustrating the first semiconductor chip 11 which is one of individual chips cut out from the wafer 10 of the semiconductor device according to the sixth embodiment of the present invention;

FIG. 22D is a diagram illustrating the mounting of the first semiconductor chip 11 to the interposer substrate 1 of the semiconductor device according to the sixth embodiment of the present invention;

FIG. 22E is a diagram illustrating a state where a first sealing resin 71 is formed between the first semiconductor chip 11 and the interposer substrate 1 of the semiconductor device according to the sixth embodiment of the present invention;

FIG. 22F is a diagram illustrating the mounting of the second semiconductor chip 12 to the first semiconductor chip 11 of the semiconductor device according to the sixth embodiment of the present invention;

FIG. 22G is a diagram illustrating a state where a second sealing resin 72 is formed between the first semiconductor chip 11 and the second semiconductor chip 12 of the semiconductor device according to the sixth embodiment of the present invention;

FIG. 22H is a diagram illustrating a state where solder balls 4 are formed on soldering lands 3 of the bottom surface of the interposer substrate 1 of the semiconductor device according to the sixth embodiment of the present invention;

FIG. 23A is a diagram illustrating the wafer 10 of the semiconductor device according to a seventh embodiment of the present invention;

FIG. 23B is a diagram illustrating a cross section of the wafer 10 of the semiconductor device according to the seventh embodiment of the present invention;

FIG. 23C is a diagram illustrating the first semiconductor chip 11 which is one of individual chips cut out from the wafer 10 of the semiconductor device according to the seventh embodiment of the present invention;

FIG. 23D is a diagram illustrating the mounting of the first semiconductor chip 11 to the interposer substrate 1 of the semiconductor device according to the seventh embodiment of the present invention;

FIG. 23E is a diagram illustrating a state where the first sealing resin 71 is formed between the first semiconductor chip 11 and the interposer substrate 1 included in the semiconductor device according to the seventh embodiment of the present invention;

FIG. 23F is a diagram illustrating the mounting of the second semiconductor chip 12 to the first semiconductor chip 11 of the semiconductor device according to the seventh embodiment of the present invention;

FIG. 23G is a diagram illustrating a state where the second sealing resin 72 is formed between the first semiconductor chip 11 and the second semiconductor chip 12 included in the semiconductor device according to the seventh embodiment of the present invention;

FIG. 23H is a diagram illustrating a state where the solder balls 4 are formed on the soldering lands 3 which are disposed on the bottom surface of the interposer substrate 1 of the semiconductor device according to the seventh embodiment of the present invention;

FIG. 24A is a diagram illustrating the wafer 10 of the semiconductor device according to an eighth embodiment of the present invention;

FIG. 24B is a diagram illustrating a cross section of the wafer 10 of the semiconductor device according to the eighth embodiment of the present invention;

FIG. 24C is a diagram illustrating the first semiconductor chip 11 which is one of individual chips cut out from the wafer 10 of the semiconductor device according to the eighth embodiment of the present invention;

FIG. 24D is a diagram illustrating a state where a first resin layer 81 is formed around the periphery of each first bump 51 of the first semiconductor chip 11 of the semiconductor device according to the eighth embodiment of the present invention;

FIG. 24E is a diagram illustrating a state where the first resin layer 81 is formed around the periphery of each first bump 51 of the first semiconductor chip 11 of the semiconductor device according to the eighth embodiment of the present invention;

FIG. 24F is a diagram illustrating the mounting of the first semiconductor chip 11 to the interposer substrate 1 of the semiconductor device according to the eighth embodiment of the present invention;

FIG. 24G is a diagram illustrating a state where the first sealing resin 71 is formed between the first semiconductor chip 11 and the interposer substrate 1 of the semiconductor device according to the eighth embodiment of the present invention;

FIG. 24H is a diagram illustrating the mounting of the second semiconductor chip 12 to the first semiconductor chip 11 of the semiconductor device according to the eighth embodiment of the present invention;

FIG. 24I is a diagram illustrating a state where the second sealing resin 72 is formed between the first semiconductor chip 11 and the second semiconductor chip 12 of the semiconductor device according to the eighth embodiment of the present invention;

FIG. 24J is a diagram illustrating a state where the solder balls 4 are formed on the soldering lands 3 of the bottom surface of the interposer substrate 1 of the semiconductor device according to the eighth embodiment of the present invention;

FIG. 25 is a diagram illustrating a transfer method according to a ninth embodiment of the present invention;

FIG. 26 is a diagram illustrating a screen printing method according to the ninth embodiment of the present invention;

FIG. 27 is a diagram illustrating a screen printing method according to the ninth embodiment of the present invention;

FIG. 28 is a cross sectional view of a semiconductor device 1000 according to the prior art;

FIG. 29 is an enlarged view of a portion 1100 in which semiconductor chips included in the semiconductor device 1000 are joined to each other;

FIG. 30 shows that in a semiconductor device 1200 formed by a single semiconductor chip, deformation of the semiconductor chip occurs;

FIG. 31 shows that in a semiconductor device 1300 formed by semiconductor chips stacked in multi-layers, deformation of the semiconductor chips occurs; and

FIG. 32 is a diagram illustrating a semiconductor device 1400 in which a resin ball is disposed in an area where the semiconductor chips are greatly deformed.

### DESCRIPTION OF THE PREFERRED EMBODIMENTS

Hereinafter, embodiments of the present invention will be described with reference to the drawings.

### First Embodiment

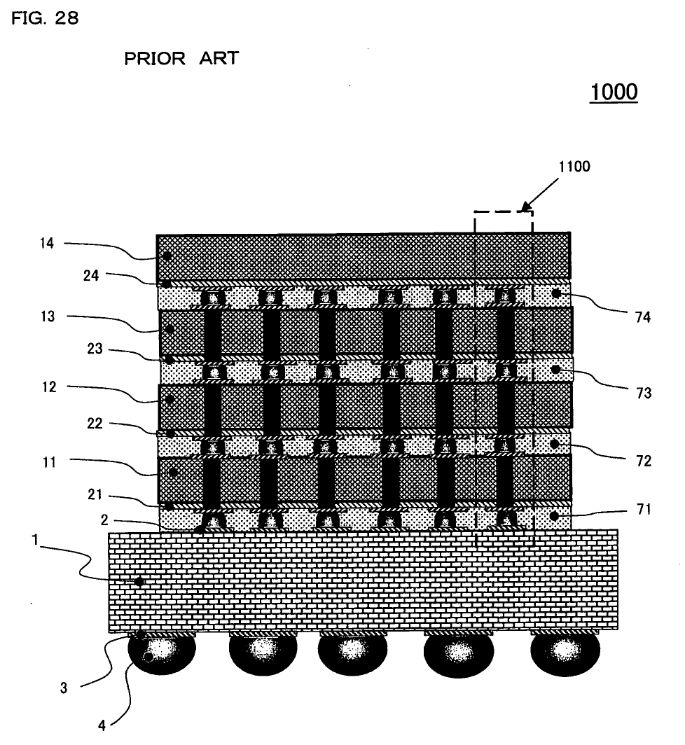

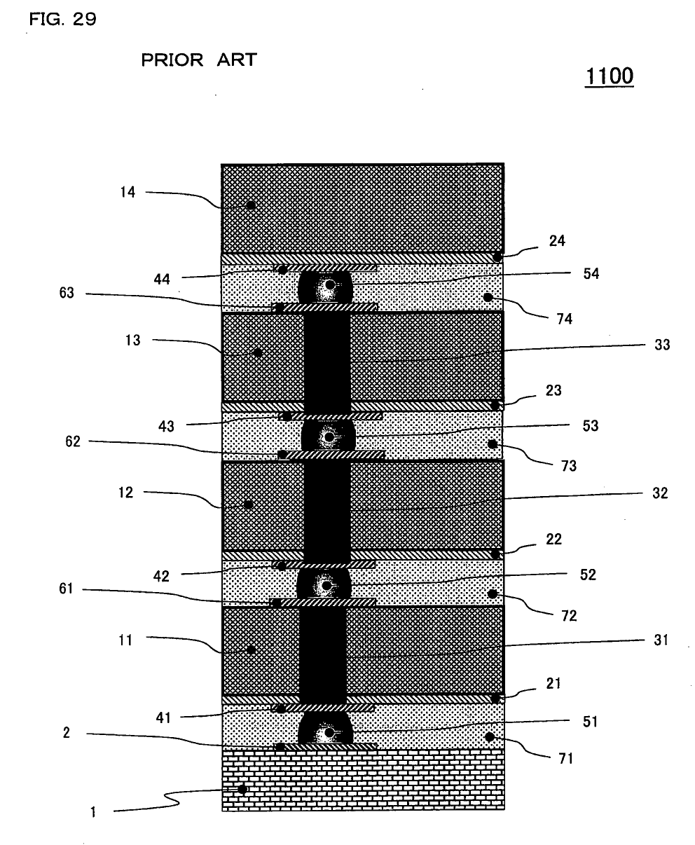

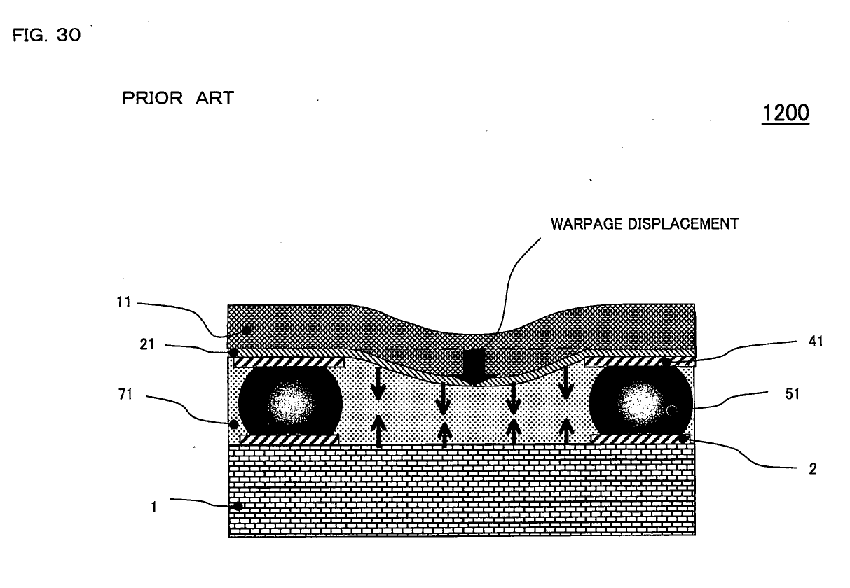

A structure of a semiconductor device according to a first embodiment of the present invention is basically the same as that of the semiconductor device 1000 according to the prior art shown in FIGS. 28 and 29. The semiconductor device according to the first embodiment of the present invention is the same as the semiconductor device 1000 according to the prior art except for arrangement positions of a through via, an electrode pad and a bump. In the semiconductor device 1000 according to the prior art, a position at which a through via, an electrode pad and a bump are arranged on one semiconductor chip is the same as a position at which the above three components are arranged on another semiconductor chip. In contrast, in the semiconductor device according to the first embodiment of the present invention, a position at which a through via, an electrode pad and a bump are arranged on one semiconductor chip is shifted from a position at which the above three components are arranged on another semiconductor chip. Hereinafter, the detailed structure of the semiconductor device according to the first embodiment of the present invention will be described. Note that any components included in the semiconductor device as those included in the conventional semiconductor device 1000 shown in FIGS. 28 and 29 will be denoted as the same reference numerals, and will not be further described below.

### Example 1

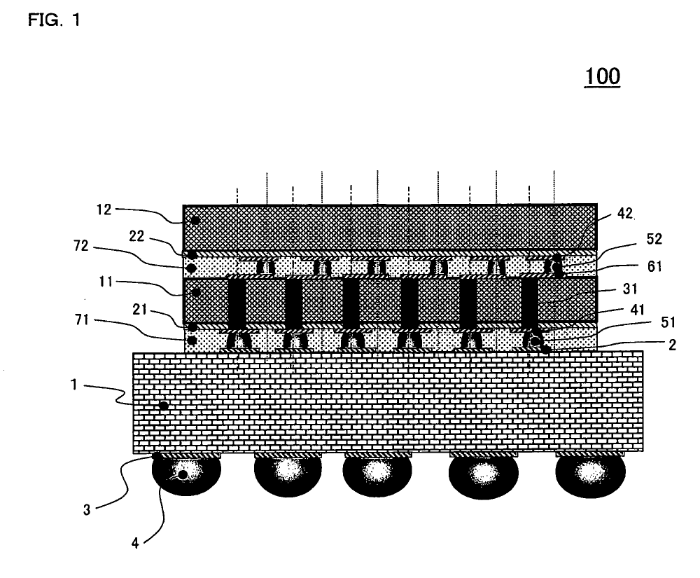

FIG. 1 is a diagram illustrating a semiconductor device 100 according to the first embodiment of the present invention. In FIG. 1, the semiconductor device 100 is a double-layered semiconductor device in which the first semiconductor chip 11 and the second semiconductor chip 12 are connected onto the interposer substrate 1 by using the flip-chip method. In FIG. 1, the structure of the semiconductor device 100 is the same as that the semiconductor device 1000 of the prior art shown in FIG. 28 in that both of the semiconductor devices include the interposer substrate 1, the first semiconductor chip 11 and the second semiconductor chip 12. A first through via 31 is formed within the first semiconductor chip 11 for conducting electricity between a top main surface and a bottom surface of the first semiconductor chip 11. On the first circuit element surface 21, a first electrode pad 41 is disposed at a position at which the first through via 31 is formed, and the first bump 51 is further formed on the first electrode pad 41. However, unlike the semiconductor device 1000 shown in FIG. 28, on the bottom surface of the first semiconductor chip 11, a position at which the second bump 52 is arranged is different from a position at which the first through via 31 is formed. Between the first semiconductor chip 11 and the second semiconductor chip 12, the second bump 52 is arranged at a position extending vertically upward from a midpoint between adjacent first bumps 51. That is, on the first semiconductor chip 11, the first electrode pads 41 form a first electrode pad arrangement, and on the second semiconductor chip 12, the second electrode pad 42 is arranged at a midpoint between arrangement positions of the adjacent first electrode pads 41 so as to form a second electrode pad arrangement which is different from the first electrode pad arrangement.

Furthermore, on the bottom surface of the first semiconductor chip 11 of the semiconductor device 1000 shown in FIGS. 28 and 29, the second bump 52 is arranged at a position at which the first through via 31 is formed. Therefore, the size of the first via pad 61 is approximately equal to that of the second bump 52. However, in the semiconductor device 100 according to the present embodiment, a position at which the second bump 52 is arranged is shifted from a position at which the first through via 31 is formed. Therefore, the size of the first via pad 61 is within a range from a position where the first through via 31 is formed to a position where the second bump 52 is arranged. The second semiconductor chip 12 is electrically connected to the first semiconductor chip 11 by bonding the second bump 52 to the first via pad 61 of the first semiconductor chip 11.

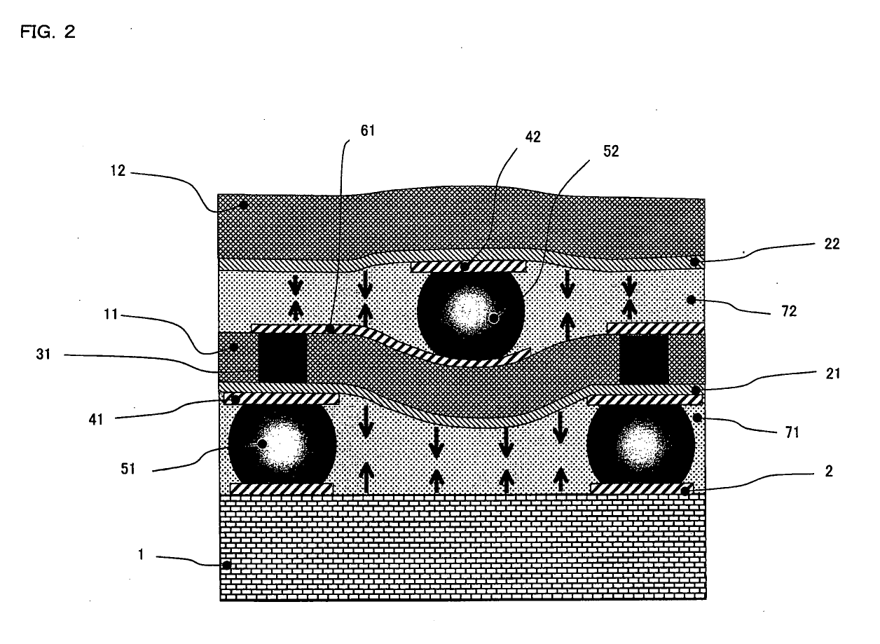

FIG. 2 is an enlarged view illustrating the detailed structure of a portion in which the interposer substrate 1, the first semiconductor chip 11 and the second semiconductor chip 12 included in the semiconductor device 100 shown in FIG. 1 are joined to each other. Between the first semiconductor chip 11 and the second semiconductor chip 12, the second bump 52 is arranged at a position extending vertically upward from a midpoint between adjacent first bumps 51, which are disposed between the interposer substrate 1 and the first semiconductor chip 11.

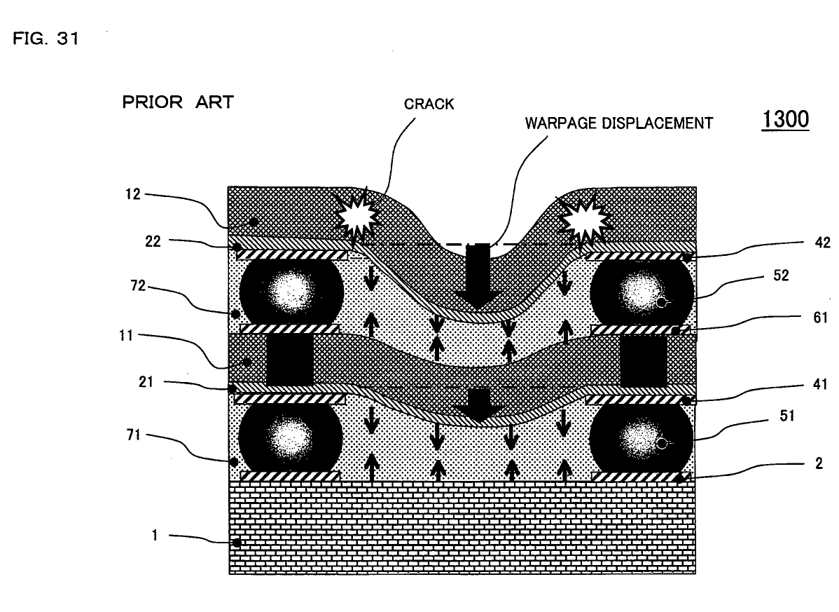

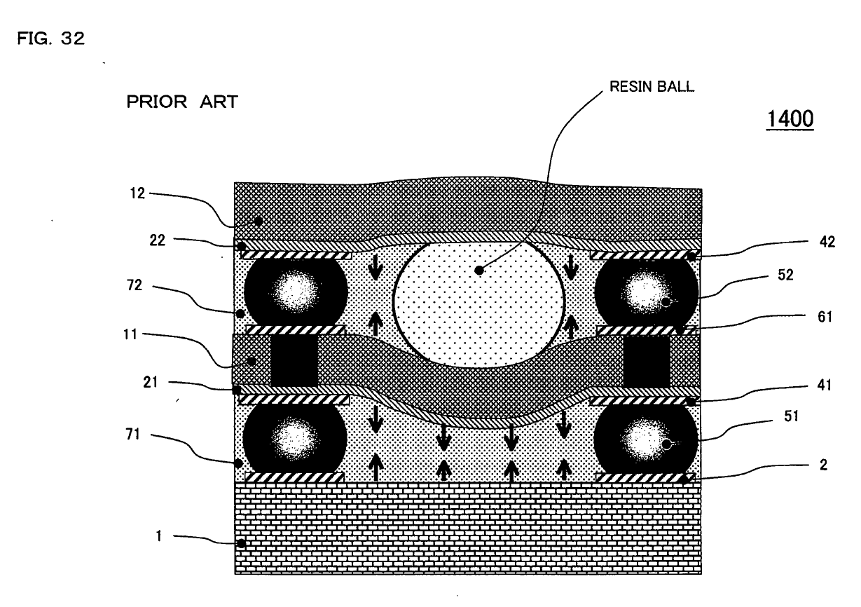

As described above, in the semiconductor device 100 according to the present embodiment, the second bump 52 is disposed at a position of the greatest deformation of the second semiconductor chip 12 shown in FIG. 31, thereby preventing the second semiconductor chip 12 from being deformed. Furthermore, in the semiconductor device 100 according to the present embodiment, it is unnecessary to provide the resin balls as shown in FIG. 32 for preventing each semiconductor chip from being deformed.

### Example 2

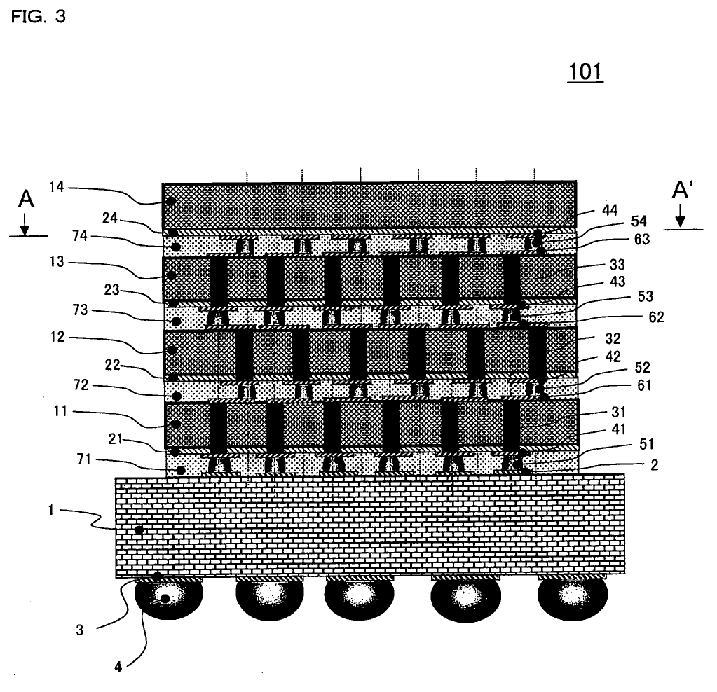

An example 1 has described the semiconductor device 100 in which two semiconductor chips are stacked in layers. In an example 2, a semiconductor device in which four semiconductor chips are stacked in layers will be described. FIG. 3 is a diagram illustrating a semiconductor device 101 according to the first embodiment of the present invention. In FIG. 3, the structure of the semiconductor device 101 is basically the same as that of the semiconductor device 1000 according to the prior art shown in FIG. 28, and the semiconductor device 101 is a quadruple-layered semiconductor device in which the interposer substrate 1 and the first to fourth semiconductor chips 11 to 14 are connected to each other by using a flip-chip method. Note that in the semiconductor device 101, a through via, an electrode pad and a bump, all of which are formed on each semiconductor chip, are arranged in the same manner as the semiconductor device 100 shown in FIGS. 1 and 2. That is, in the semiconductor device 101, the third and fourth semiconductor devices 13 and 14 are connected to each other in the same manner as the first and second semiconductor chips 11 and 12 by using the flip-chip method, and the third and fourth semiconductor chips 13 and 14 having the above-mentioned structure are stacked on the second semiconductor chip 12 of the semiconductor device 100.

Arrangements of the first to fourth electrode pads 41 to 44 of the respective first to fourth semiconductor chips 11 to 14 included in the semiconductor device 101 will be further described. On the first semiconductor chip 11, the first electrode pads 41 form a first electrode pad arrangement. Similarly, on the third semiconductor chip 13, the third electrode pads 43 form the first electrode pad arrangement. On the second semiconductor chip 12, each second electrode pad 42 is arranged at a midpoint between positions where the first electrode pads 41 or the third electrode pads 43 are arranged so as to form a second electrode pad arrangement which is different from the first electrode pad arrangement. Similarly, on the fourth semiconductor chip 14, each fourth electrode pad 44 is arranged at amid point between positions where the first electrode pads 41 or the third electrode pads 43 are arranged so as to form the second electrode pad arrangement which is different from the first electrode pad arrangement. That is, on the first to fourth semiconductor chips 11 to 14, the first and second electrode pad arrangements are alternately formed.

As described above, on the first to fourth semiconductor chips 11 to 14 included in the semiconductor device 101, the first and the second electrode pad arrangements are alternately formed. Therefore, positions of the greatest deformation differ in each semiconductor chip. Furthermore, in the semiconductor chips stacked in multi-layers, the cumulative amount of the deformation is reduced. Therefore, in the semiconductor device 101, the deformation of each of the semiconductor chips stacked in layers can be reduced as compared to the semiconductor device 1000 shown in FIGS. 28 and 29 where the same electrode pad arrangement is formed on each of the semiconductor chips stacked in layers.

In the example 2, the electrode pad arrangement of the first semiconductor chip 11 is the same as that of the semiconductor chip 13, and the electrode pad arrangement of the second semiconductor chip 12 is the same as that of the semiconductor chip 14. However, the electrode pad arrangements of the first to fourth semiconductor chips 11 to 14 may be different from each other.

### Example 3

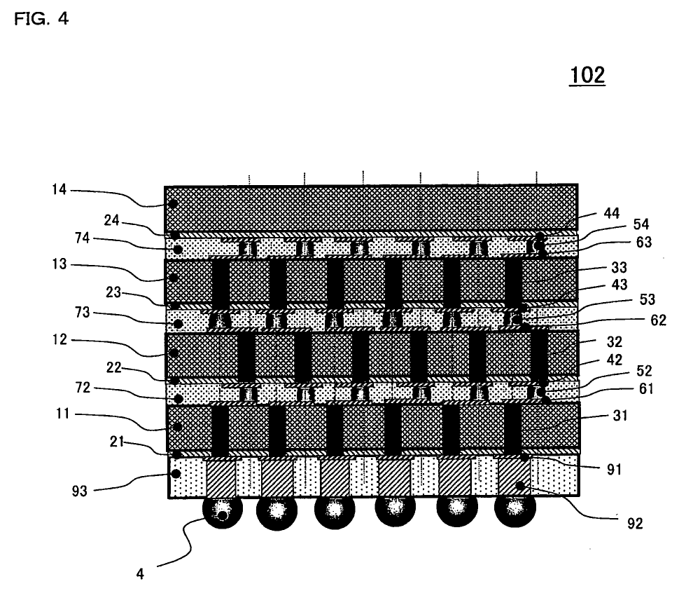

In an example 3, a rewiring semiconductor device will be described. In a compact package having a size of 200 pins or less, a rewiring structure is formed without using an interposer substrate in a semiconductor device in order to realize an ultra-compact package structure such as a wafer level chip size package. FIG. 4 is a diagram illustrating a semiconductor device 102 according to the first embodiment of the present invention. In the semiconductor device 102, instead of the interposer substrate 1 of the semiconductor device 101 shown in FIG. 3, a rewiring 91 is loaded from an electrode pad on silicon (Si), and a copper post 92 is placed at a position of the rewiring 91, and then the periphery of the copper post 92 is sealed with resin 93. The aforementioned steps are executed on a wafer, and then the wafer in which those steps have been executed is cut into individual semiconductor chips, thereby making it possible to create a package having the same size as that of a silicon chip. Therefore, the size of a package of the semiconductor device 102 can be smaller than that of a package of the semiconductor device 101 shown in FIG. 3.

It is understood that such a rewiring semiconductor device 102 can produce the same effect as that obtained by the semiconductor device 101 mentioned above.

### Example 4

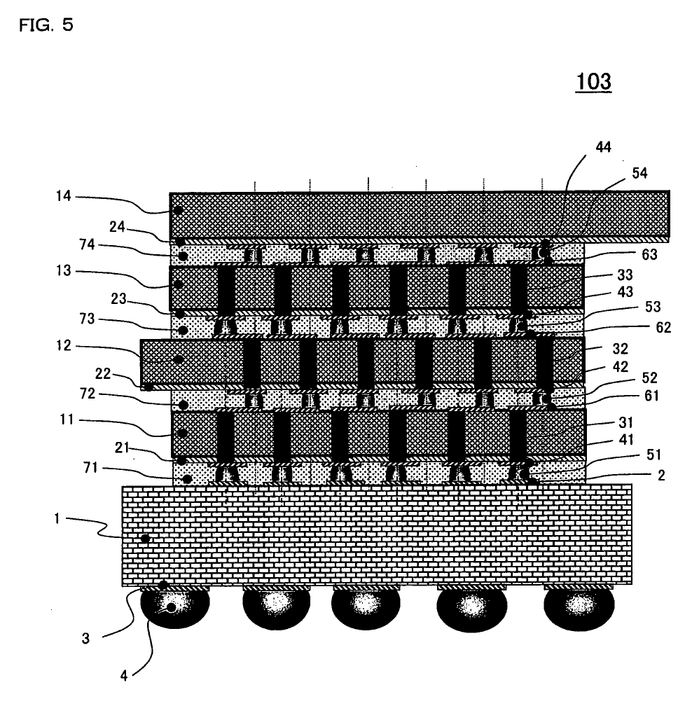

FIG. 5 is a diagram illustrating a semiconductor device 103 according to the first embodiment of the present invention. The semiconductor device 103 shown in FIG. 5 differs from the semiconductor device 101 shown in FIG. 3 in that in the semiconductor device 103, the sizes of the semiconductor chips stacked in multi-layers are different from each other. As described above, it is understood that the same effect can be obtained even if the sizes of the first to fourth semiconductor chips 11 to 14 are different from each other.

As described above, in the semiconductor devices 100 to 103 according to the first embodiment of the present invention, the first electrode pad arrangement and the second electrode pad arrangement are alternately formed on the semiconductor chips stacked in multi-layers, thereby reducing the deformation of each semiconductor chip caused by the shrinkage of sealing resin, and not requiring the resin balls to be disposed for preventing each semiconductor chip from being deformed. Therefore, even if each semiconductor chip to be stacked is thin, it is possible to prevent a crack from being generated due to stress concentrated on one position. As a result, a high-density circuit in which a great number of electrodes are connected at narrow pitches can be provided while reducing characteristic variation of semiconductor elements formed on a circuit element surface.

Note that as another example, a semiconductor device may have a structure in which a portion of a semiconductor is connected by wire bonding, and the entirety of the semiconductor chip is sealed with resin. A method of sealing the entirety of the semiconductor chip with resin includes a transfer molding process, printing encapsulation system and the like.

### Example 5

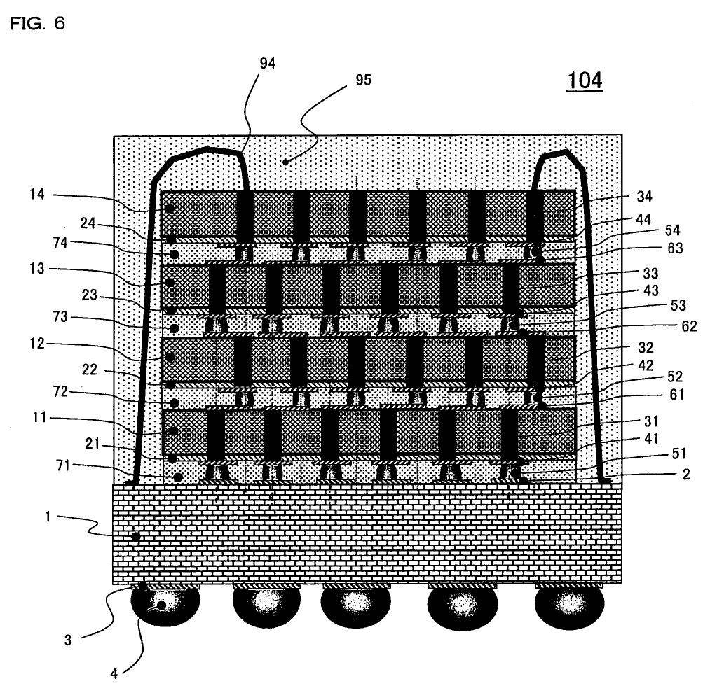

FIG. 6 is a diagram illustrating a semiconductor device 104 according to the first embodiment of the present invention. In the semiconductor device 104, a fourth through via 34 is also provided within the fourth semiconductor chip 14 which is the uppermost layer of the semiconductor device 101 shown in FIG. 3, and a wire 94 is connected from a bottom surface of the fourth semiconductor chip 14 to the interposer substrate 1 by wire bonding. The entirety of the semiconductor chip connected by wire bonding in such a manner as described above is sealed with mold resin 95.

### Example 6

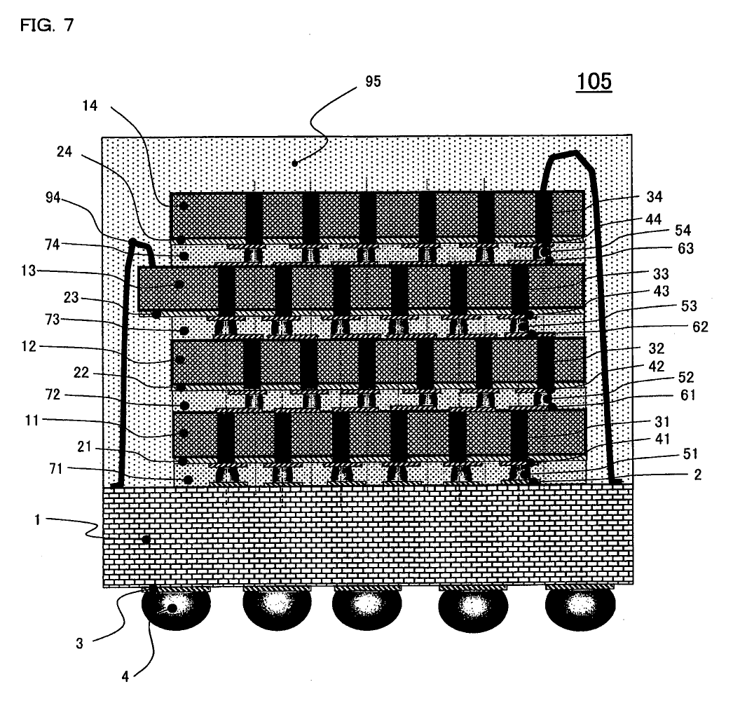

FIG. 7 is a semiconductor device 105 according to the first embodiment of the present invention. The semiconductor device 105 shown in FIG. 7 differs from the semiconductor device 104 shown in FIG. 6 in that in FIG. 7, the wire 94 is connected from, instead of the uppermost fourth semiconductor chip 14, one of the semiconductor chips stacked in multi-layers, e.g., the third semiconductor chip 13 which is the third layer in the stack, to the interposer substrate 1 by wire bonding.

As described above, it is understood that the same effect can be obtained when using the semiconductor devices 104 and 105 according to the first embodiment of the present invention.

### Second Embodiment

A structure of the semiconductor device according to a second embodiment of the present invention is basically the same as that according to the first embodiment of the present invention. Specifically, positions at which through vias are formed on each semiconductor chip are different between the first and second embodiments. In the semiconductor device according to the first embodiment of the present invention, on the circuit element surface of each of the semiconductor chips stacked in multi-layers, the electrode pad is arranged at a position at which the through via is formed so as to form the bump on the circuit element surface. In contrast, in the semiconductor device according to the second embodiment of the present invention, the bump is formed at a position shifted from a position at which the through via is formed on each of the semiconductor chips stacked in multi-layers. Hereinafter, the detailed structure of the semiconductor device according to the second embodiment of the present invention will be described.

### Example 1

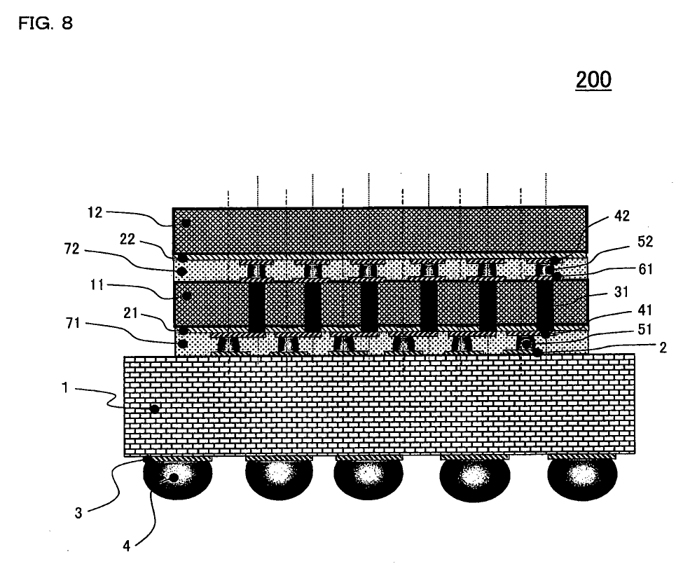

FIG. 8 is a diagram illustrating a semiconductor device 200 according to the second embodiment of the present invention. In FIG. 8, the semiconductor device 200 is a double-layered semiconductor device in which the first semiconductor chip 11 and the second semiconductor chip 12 are connected onto the interposer substrate 1 by using the flip-chip method. In FIG. 8, a structure of the semiconductor device 200 is basically the same as that of the semiconductor device 100 shown in FIG. 1 according to the first embodiment of the present invention. In the semiconductor device 200, the first through via 31 is formed within the first semiconductor chip 11. On the circuit element surface 21 which is a top main surface of the first semiconductor chip 11, the first bump 51 is formed at a position shifted from a position at which the first through via 31 is formed. On the bottom surface of the first semiconductor chip 11, the first via pad 61 is arranged at a position at which the first through via is formed, so as to be joined to the second bump 52 of the second semiconductor chip. As already described in the first embodiment, the second bump 52 is disposed at a position extending vertically upward from a midpoint between adjacent first bumps 51.

Furthermore, in the semiconductor device 100 according to the first embodiment of the present invention, on the bottom surface of the first semiconductor chip 11, the size of the first via pad 61 is within a range from a position where the first through via 31 is formed to a position where the second bump 52 is formed. In contrast, in the semiconductor device 200 according to the present embodiment, the size of the first electrode pad 41 formed on the top surface of the first semiconductor chip 11 is within a range from a position where the first through via 31 is formed to a position where the first bump 51 is formed.

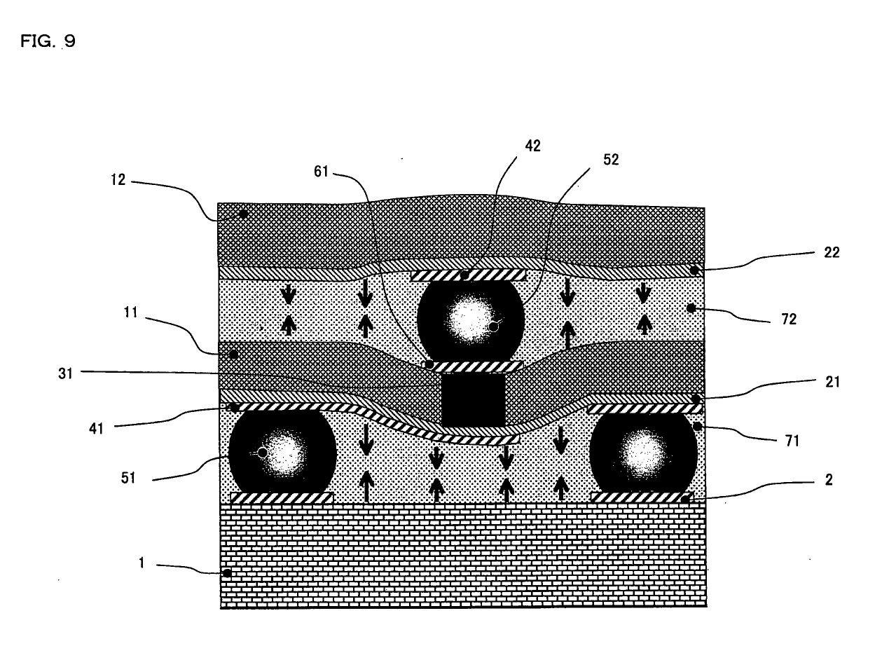

FIG. 9 is an enlarged view illustrating the detailed structure of a portion in which the interposer substrate 1, the first semiconductor chip 11 and the second semiconductor chip 12 included in the semiconductor device 200 shown in FIG. 8 are joined to each other. Between the first semiconductor chip 11 and the second semiconductor chip 12, the second bump 52 is arranged at a position extending vertically upward from a midpoint between adjacent first bumps 51, which are disposed between the interposer substrate 1 and the first semiconductor chip 11.

As described above, the second bump 52 is disposed at a position of the greatest deformation of the second semiconductor chip 12 shown in FIG. 31, thereby preventing the second semiconductor chip 12 from being deformed. Furthermore, in the semiconductor device 200 according to the present embodiment, it is unnecessary to provide the resin balls as shown in FIG. 32 for preventing each semiconductor chip from being deformed.

### Example 2

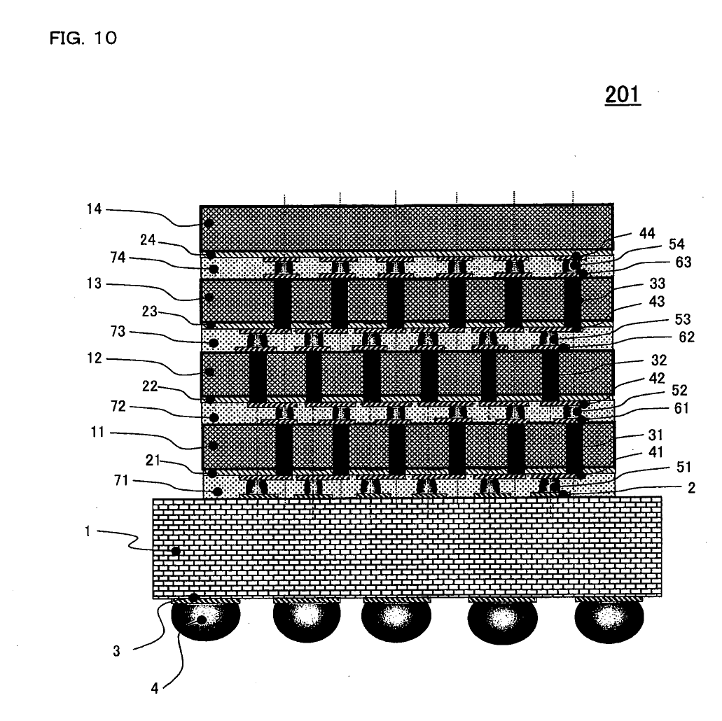

An above example 1 has described the semiconductor device 200 in which two semiconductor chips are stacked in layers. In an example 2, a semiconductor device in which four semiconductor chips are stacked in layers will be described. FIG. 10 is a diagram illustrating a semiconductor device 201 according to the second embodiment of the present invention. In FIG. 10, the structure of the semiconductor device 201 is basically the same as that of the semiconductor device 1000 according to the prior art shown in FIG. 28, and the semiconductor device 201 is a quadruple-layered semiconductor device in which the interposer substrate 1 and the first to fourth semiconductor chips 11 to 14 are connected to each other by using the flip-chip method. Note that in the semiconductor device 201, positions at which a through via, an electrode pad and a bump are arranged on each semiconductor chip are the same as those at which the above three components are arranged on each semiconductor chip of the semiconductor device 200 shown in FIGS. 8 and 9. That is, in the semiconductor device 201, the third and fourth semiconductor chips 13 and 14 are connected to each other in the same manner as the first and second semiconductor chips 11 and 12 by using the flip-chip method, and the third and fourth semiconductor chips 13 and 14 having the above-mentioned structure are stacked on the second semiconductor chip 12 of the semiconductor device 200 shown in FIGS. 8 and 9. In this case, it is possible to reduce the deformation of each semiconductor chip, as described in the first embodiment of the present invention.

As described above, in the semiconductor devices 200 to 201 according to the second embodiment of the present invention, the first electrode pad arrangement and the second electrode pad arrangement are alternately formed on the semiconductor chips stacked in multi-layers, thereby reducing the deformation of each semiconductor chip caused by the shrinkage of sealing resin, and not requiring the resin balls to be disposed for preventing each semiconductor chip from being deformed. Therefore, even if each semiconductor chip to be stacked is thin, it is possible to prevent a crack from being generated due to stress concentrated on one position. As a result, a high-density circuit in which a great number of electrodes are connected at narrow pitches can be provided while reducing characteristic variation of semiconductor elements formed on a circuit element surface.

### Third Embodiment

A structure of the semiconductor device according to a third embodiment of the present invention differs from that of the semiconductor device according to the first embodiment of the present invention in that in the semiconductor according to the third embodiment, a resin layer is additionally provided around the periphery of each bump.

### Example

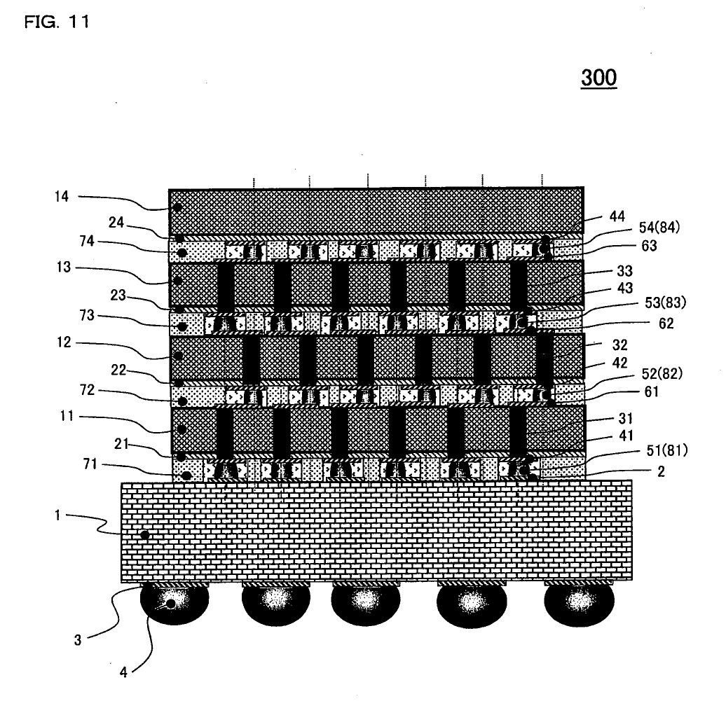

FIG. 11 is a diagram illustrating a semiconductor device 300 according to the third embodiment of the present invention. In FIG. 11, a structure of the semiconductor device 300 differs from that of the semiconductor device 101 shown in FIG. 3 according to the first embodiment of the present invention in that in the semiconductor device 300, first to fourth resin layers 81 to 84 are additionally provided. The first to fourth resin layers 81 to 84 are formed around the peripheries of the first to fourth bumps 51 to 54, respectively.

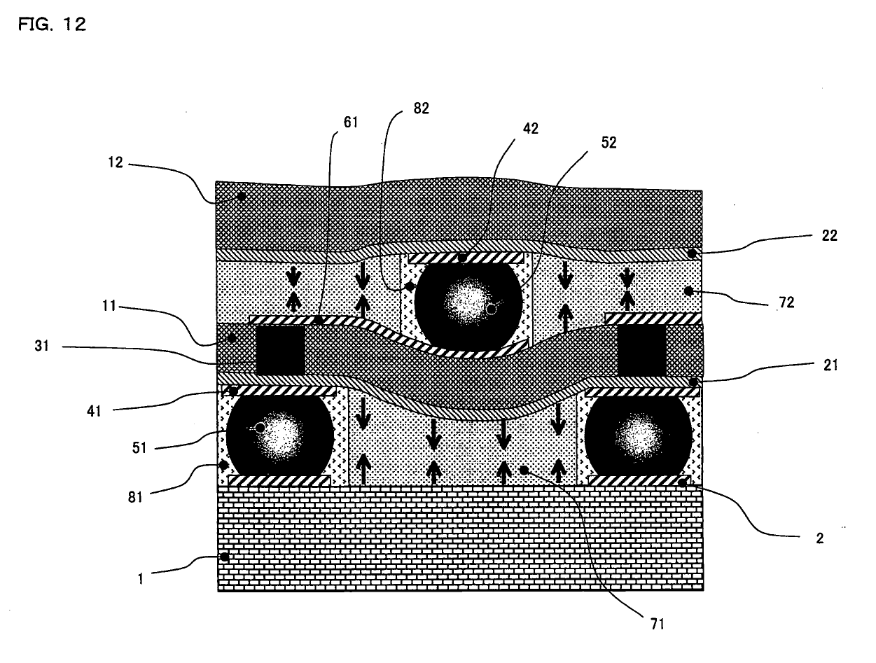

FIG. 12 is an enlarged view illustrating the detailed structure of the interposer substrate 1, the first semiconductor chip 11 and the second semiconductor chip 12 included in the semiconductor device 300 shown in FIG. 11 are joined to each other. The first resin layer 81 covers around the periphery of the first bump 51 for electrically connecting the interposer substrate 1 and the first semiconductor chip 11. Similarly, the second resin layer 82 covers around the periphery of the second bump 52 for electrically connecting the first semiconductor chip 11 to the second semiconductor chip 12.

Note that curing shrinkage rates of the first to fourth resin layers 81 to 84 formed around the peripheries of the first to fourth bumps 51 to 54 are lower than those of the first to fourth sealing resins 71 to 74, respectively. Also, thermal expansion coefficients of the first to fourth resin layers 81 to 84 are lower than those of the first to fourth sealing resins 71 to 74, respectively.

As described above, the first to fourth resin layers 81 to 84 cover around the peripheries of the first to fourth bumps 51 to 54, respectively, thereby reducing the shrinkage of resin formed around the periphery of the bump of each of the semiconductor chips. Therefore, in the vicinity of the root of each of the first to fourth bumps 51 to 54, stress caused by resin shrinkage is reduced in the vicinity of the root of each of the first to fourth bumps 51 to 54, thereby reducing the rapid deformation of each semiconductor chip and thus stress applied to the circuit element surface is accordingly reduced.

As described above, according to the semiconductor device 300 of the third embodiment of the present invention, the first to fourth bumps 51 to 54 are formed around the peripheries of the first to fourth resin layers 81 to 84, respectively, the deformation of each semiconductor chip caused by resin shrinkage can be further reduced as compared to the semiconductor device according to the first and second embodiments of the present invention. Therefore, even if each semiconductor chip to be stacked is thin, it is possible to prevent a crack from being generated due to stress concentrated on one position. As a result, a high-density circuit in which a great number of electrodes are connected at narrow pitches can be provided while reducing characteristic variation of semiconductor elements formed on a circuit element surface.

Note that in the semiconductor device 300 of the present embodiment, resin layers cover around the peripheries of all bumps. However, the present invention is not limited thereto. For example, the resin layer may be formed only around the periphery of a bump arranged at a position to which a large amount of stress is applied or a bump arranged for connecting ultra-thin semiconductor chips.

### Fourth Embodiment

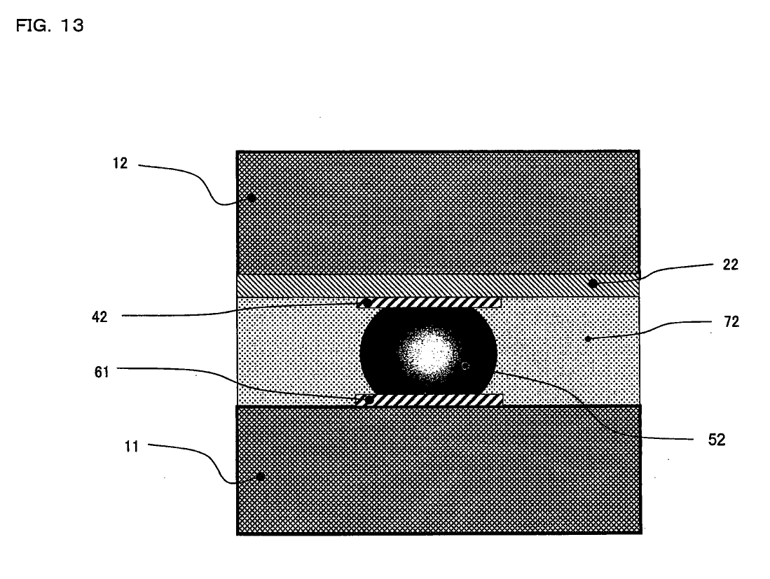

Hereinafter, the present embodiment will describe the detailed structure of each bump for conducting electricity between the interposer substrate and the lowermost semiconductor chip or between the other semiconductor chips adjacent to each other, all of the above components being included in the semiconductor device according to the first to third embodiments of the present invention. FIGS. 13 to 15 are enlarged views, each illustrating a portion in which adjacent semiconductor chips included in the semiconductor device according to the first to third embodiments of the present invention are joined to each other. FIGS. 13 to 15 show examples of a portion in which the first semiconductor chip 11 and the second semiconductor chip 12 are joined to each other.

### Example 1

As shown in FIG. 13, a solder ball is used as the second bump 52, thereby conducting electricity between the first semiconductor chip 11 and the second semiconductor chip 12.

### Example 2

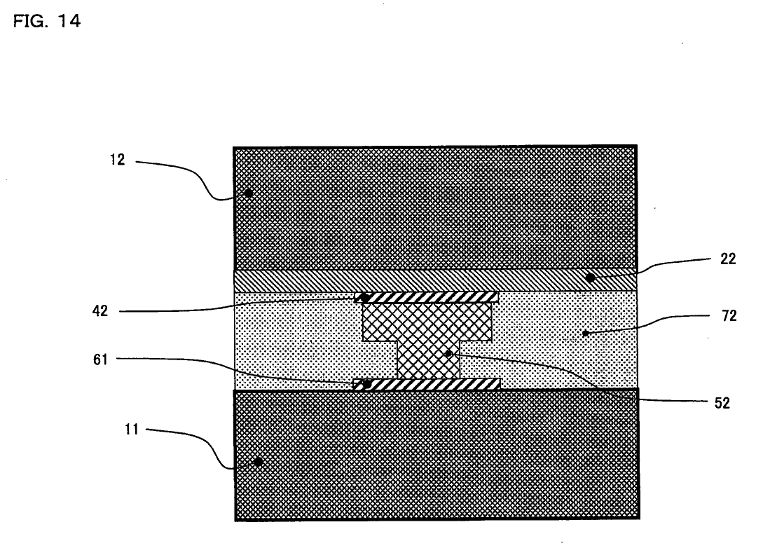

As shown in FIG. 14, a metallic electrode is used as the second bump 52, thereby conducting electricity between the first semiconductor chip 11 and the second semiconductor chip 12.

### Example 3

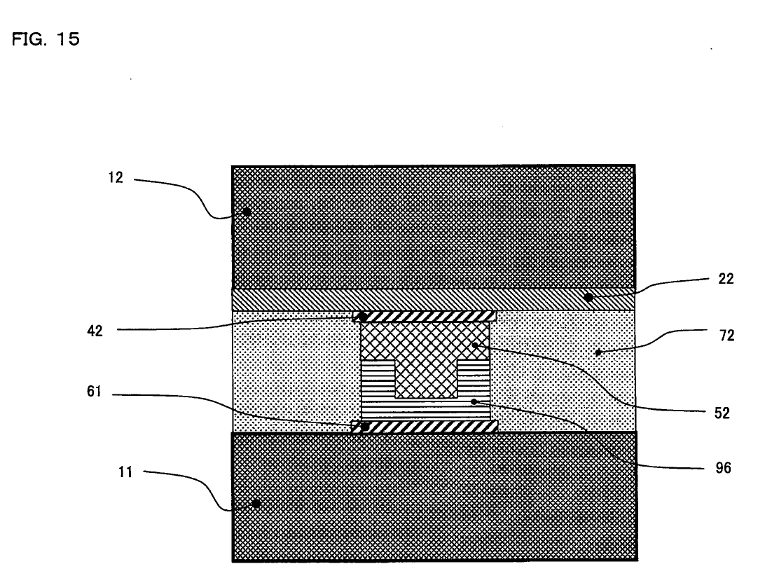

As shown in FIG. 15, a solder ball or a metallic electrode is used as the second bump 52, and a conductive layer 96 is further interposed between the first semiconductor chip 11 and the second semiconductor chip 12, thereby conducting electricity therebetween by using the flip-chip method. As a flip-chip mounting process, a SBB (Stud Bump Bonding) process for using a silver paste material as a conductive layer is used, for example.

### Fifth Embodiment

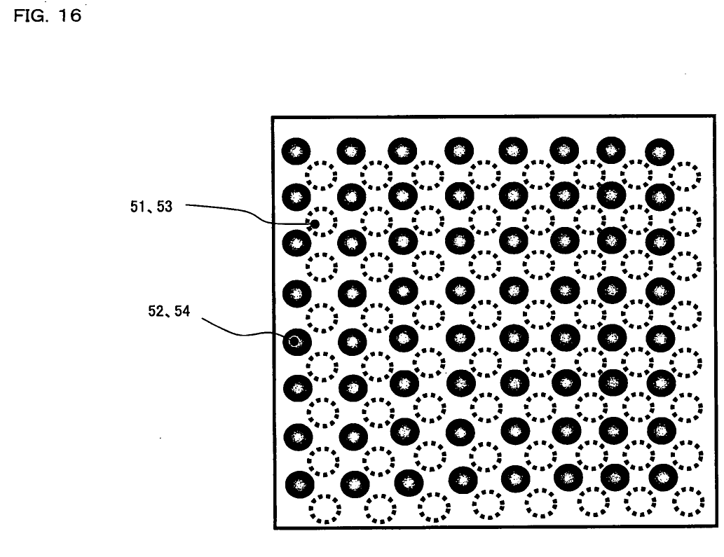

Hereinafter, the present embodiment will describe the detailed structure of a bump arrangement for conducting electricity between the interposer substrate and the lowermost semiconductor chip or between the other semiconductor chips adjacent to each other, all of the above components being included in the semiconductor device according to the first to third embodiments of the present invention. FIG. 16 is a diagram illustrating an arrangement of bumps disposed on each semiconductor chip of the semiconductor device 101 according to the first embodiment of the present invention, viewed along arrows A-A′ in FIG. 3. As already described in the first embodiment of the present invention, the first and second electrode pad arrangements are alternately formed on the first to fourth semiconductor chips 11 to 14. For example, in an area bump flip-chip process, on a semiconductor chip, each bump is arranged at a position equidistant from adjacent bumps arranged on a lower adjacent semiconductor chip, thereby forming a new bump arrangement thereon. When a position where each bump is arranged is a supporting point, a semiconductor chip is most greatly deformed at a midpoint equidistant from bumps adjacent to each other. Therefore, each bump is arranged at a position extending vertically upward from a midpoint between adjacent bumps formed on the lower adjacent semiconductor chip, so as to form a new bump arrangement, thereby efficiently reducing the deformation of the semiconductor chip.

### Example 1

As shown in FIG. 16, bumps are arranged on the entire area of each of the first to fourth semiconductor chips 11 to 14. On the second semiconductor chip 12, the bumps 52 are arranged on the entire area thereof. Similarly, on the fourth semiconductor chip 14, the bumps 54 are arranged on the entire area thereof. On the first semiconductor chip 11, the first bumps 51 are arranged in a staggered manner, each of which being located at a position shifted from a position at which each second bump 52 is arranged on the second semiconductor chip 12 or each fourth bump 54 is arranged on the fourth semiconductor chip 14. Similarly, on the third semiconductor chip 13, the third bumps 53 are arranged in a staggered manner, each of which being located at a position shifted from the position at which each second bump 52 is arranged on the second semiconductor chip 12 or each fourth bump 54 is arranged on the fourth semiconductor chip 14. On the first to fourth semiconductor chips 11 to 14, the bumps are arranged in the same matrix, and each of the semiconductor chips has the same number of the bumps arranged thereon.

Note that in the case where sealing resin is filled into a gap between the semiconductor chips stacked in multi-layers, bump electrodes are formed in the peripheral portion of each semiconductor chip. Therefore, the sealing resin is likely to flow through the bump electrodes so as to spread into the peripheral portion between semiconductor chips, and then flow toward a central portion between the semiconductor chips. Thus, air bubbles are easily generated in the central portion between the semiconductor chips. Therefore, if the bumps are arranged in such a manner as the example 1 where the bumps are uniformly arranged on the entirety of each chip, the air bubbles are not likely to be generated in the central portion between the semiconductor chips, thereby realizing a semiconductor device with high reliability of portions in which the semiconductor chips are joined to each other. Furthermore, since a support span created by the bump electrodes is shortened, the deformation of the central portion between the bump electrodes formed on each semiconductor chip is not to become greater and thus stress concentrated on the root of each bump electrode can be accordingly reduced.

As described above, according to the bump arrangement of each semiconductor chip of the fifth embodiment of the present invention, the deformation of said each semiconductor chip caused by the shrinkage of sealing resin can be reduced, whereby even if each semiconductor chip to be stacked is thin, it is possible to prevent a crack from being generated due to stress concentrated on one position. As a result, a high-density circuit in which a great number of electrodes are connected at narrow pitches can be provided while reducing characteristic variation of semiconductor elements formed on a circuit element surface. Further, it becomes possible to realize a semiconductor device with high reliability of portions in which semiconductor chips are joined to each other by high-quality filling of the portions with sealing resin.

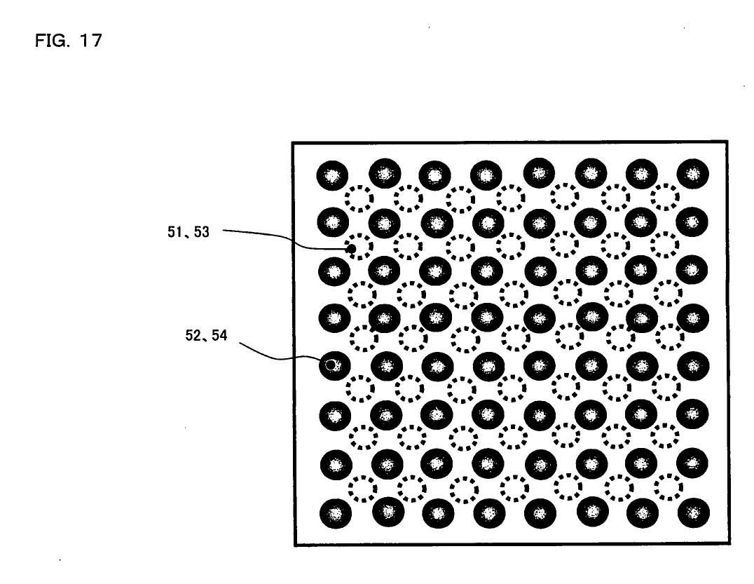

Note that the bump arrangement according to the present embodiment is not limited to the arrangement shown in FIG. 16. The following bump arrangements may also be used. FIGS. 17 to 21 are diagrams illustrating a bump arrangement of each semiconductor chip of the semiconductor device according to the first to third embodiments of the present invention mentioned above.

### Example 2

As shown in FIG. 17, bumps are arranged on the entire area of each of the first to fourth semiconductor chips 11 to 14. On the second semiconductor chip 12, the bumps 52 are arranged on the entire area thereof. Similarly, on the fourth semiconductor chip 14, the bumps 54 are arranged on the entire area thereof. On the first semiconductor chip 11, each of the first bumps 51 is arranged at a position of gravity center of the minimum rectangle formed by four bumps among the second bumps 52 arranged on the second semiconductor chip 12 or the fourth bumps 54 arranged on the fourth semiconductor chip 14. Similarly, on the third semiconductor chip 13, each of the third bumps 53 is arranged at a position of gravity center of the minimum rectangle formed by four bumps among the second bumps 52 arranged on the second semiconductor chip 12 or the fourth bumps 54 arranged on the fourth semiconductor chip 14. Unlike the example 1, in the example 2, each of the semiconductor chips has a different number of bumps arranged thereon.

### Example 3

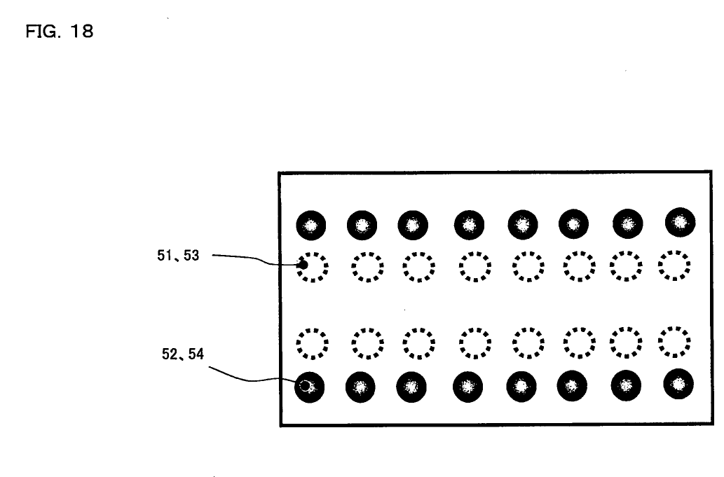

As shown in FIG. 18, bumps are arranged the periphery of only two edges of each of the first to fourth semiconductor chips 11 to 14. On the second semiconductor chip 12, the second bumps 52 are arranged along the outmost periphery thereof. Similarly, on the fourth semiconductor chip 14, the fourth bumps 54 are arranged along the outermost periphery thereof. On the first semiconductor chip 11, each of the first bumps 51 is arranged at a position on the inner side with respect to the second bumps 52 or the fourth bumps 54, the position shifted from a position at which each second bump 52 is arranged on the second semiconductor chip 12 or a position at which each fourth bump 54 is arranged on the fourth semiconductor chip 14. Similarly, each of the third bumps 53 is arranged at a position on the inner side with respect to the second bumps 52 or the fourth bumps 54, the position shifted from a position at which each second bump 52 is arranged on the second semiconductor chip 12 or a position at which each fourth bump 54 is arranged on the fourth semiconductor chip 14.

### Example 4

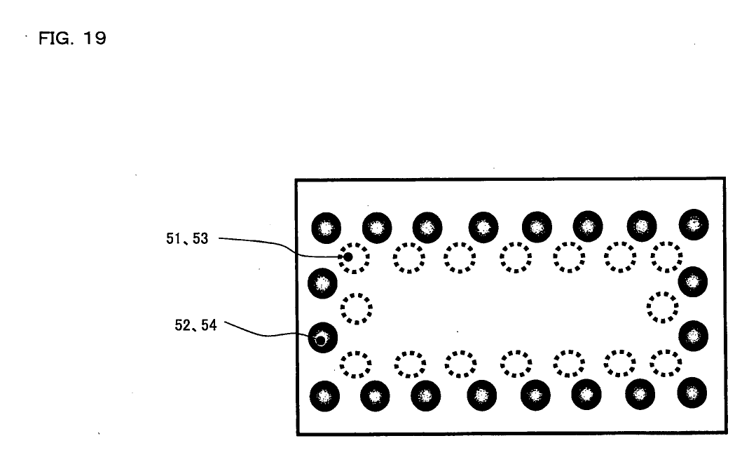

As shown in FIG. 19, bumps are arranged along the periphery of each of the first to fourth semiconductor chips 11 to 14. On the second semiconductor chip 12, the second bumps 52 are arranged along the outmost periphery thereof. Similarly, on the fourth semiconductor chip 14, the fourth bumps 54 are arranged along the outer most periphery thereof. On the first semiconductor chip 11, each of the first bumps 51 is arranged at a position on the inner side with respect to the second bumps 52 or the fourth bumps 54, the position shifted from a position at which each second bump 52 is arranged on the second semiconductor chip 12 or a position at which each fourth bump 54 is arranged on the fourth semiconductor chip 14. Similarly, each of the third bumps 53 is arranged at a position on the inner side with respect to the second bumps 52 or the fourth bumps 54, the position shifted from a position at which each second bump 52 is arranged on the second semiconductor chip 12 or a position at which each fourth bump 54 is arranged on the fourth semiconductor chip 14.

### Example 5

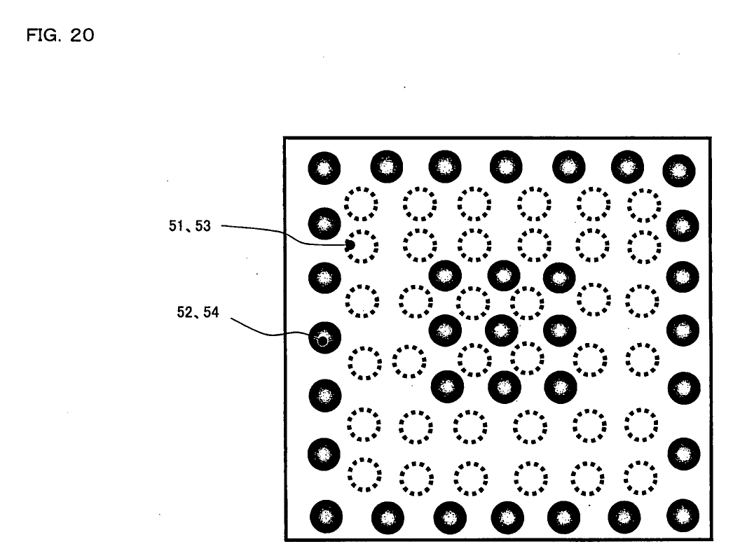

As shown in FIG. 20, bumps are arranged in central and peripheral portions of each of the first to fourth semiconductor chips 11 to 14. On the second semiconductor chip 12, the second bumps 52 are arranged in the central and outmost peripheral portions thereof. Similarly, on the fourth semiconductor chip 14, the fourth bumps 54 are arranged in the central and outmost peripheral portions thereof. On the first semiconductor chip 11, the first bumps 51 are arranged between the second bumps 52 arranged in the central portion of the second semiconductor 12 and the second bumps 52 arranged in the outmost peripheral portion of the second semiconductor chip 12, or between the fourth bumps 54 arranged in the central portion of the fourth semiconductor chip 14 and the fourth bumps 54 arranged in the outmost peripheral portion of the fourth semiconductor chip 14. Similarly, on the third semiconductor chip 13, the third bumps 53 are arranged between the second bumps 52 arranged in the central portion of the second semiconductor 12 and the second bumps 52 arranged in the outmost peripheral portion of the second semiconductor chip 12, or between the fourth bumps 54 arranged in the central portion of the fourth semiconductor chip 14 and the fourth bumps 54 arranged in the outmost peripheral portion of the fourth semiconductor chip 14. Furthermore, on the first semiconductor chip 11, the first bumps 51 are further arranged in a staggered manner at positions respectively shifted from positions at which the second bumps 52 arranged in the central portion of the second semiconductor chip 12 or the fourth bumps 54 arranged in the central portion of the fourth semiconductor chip 14. Similarly, on the third semiconductor chip 13, the third bumps 53 are further arranged in a staggered manner at positions respectively shifted from positions at which the second bumps 52 arranged in the central portion of the second semiconductor chip 12 or the fourth bumps 54 arranged in the central portion of the fourth semiconductor chip 14.

### Example 6

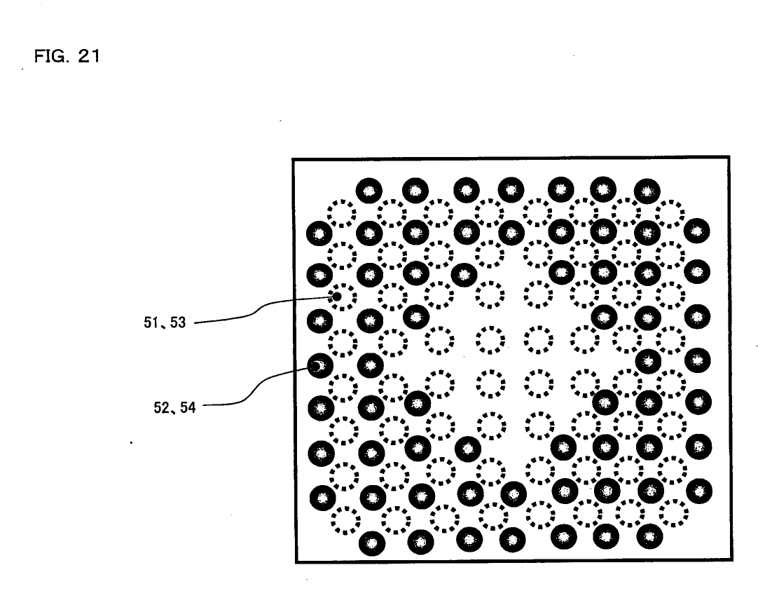

As shown in FIG. 21, bumps are arranged from a peripheral portion toward a central portion of each of the first to fourth semiconductor chips 11 to 14. On the second semiconductor chip 12, the second bumps 52 are arranged from the outmost peripheral portion toward the central portion thereof. Similarly, on the fourth semiconductor chip 14, the fourth bumps 54 are arranged from the outmost peripheral portion toward the central portion thereof. On the first semiconductor chip 11, the first bumps 51 are arranged in a staggered manner at positions respectively shifted from positions at which the second bumps 52 are arranged from the outmost peripheral portion toward the central portion of the second semiconductor chip 12 or at which the fourth bumps 54 are arranged from the outmost peripheral portion toward the central portion of the fourth semiconductor chip 14. Similarly, on the third semiconductor chip 13, the bumps 53 are arranged in a staggered manner at positions respectively shifted from positions at which the second bumps 52 are arranged from the outmost peripheral portion toward the central portion of the second semiconductor chip 12 or at which the fourth bumps 54 are arranged from the outmost peripheral portion toward the central portion of the fourth semiconductor chip 14. Furthermore, each of the first to fourth semiconductor chips 11 to 14 has the same number of the bumps arranged thereon.

Next, a fabrication method of a semiconductor device according to the present invention will be described.

### Sixth Embodiment

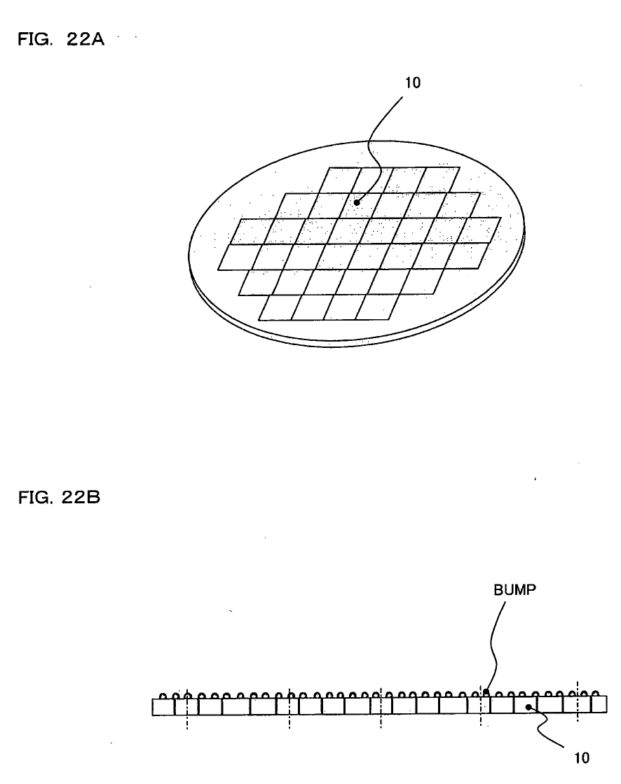

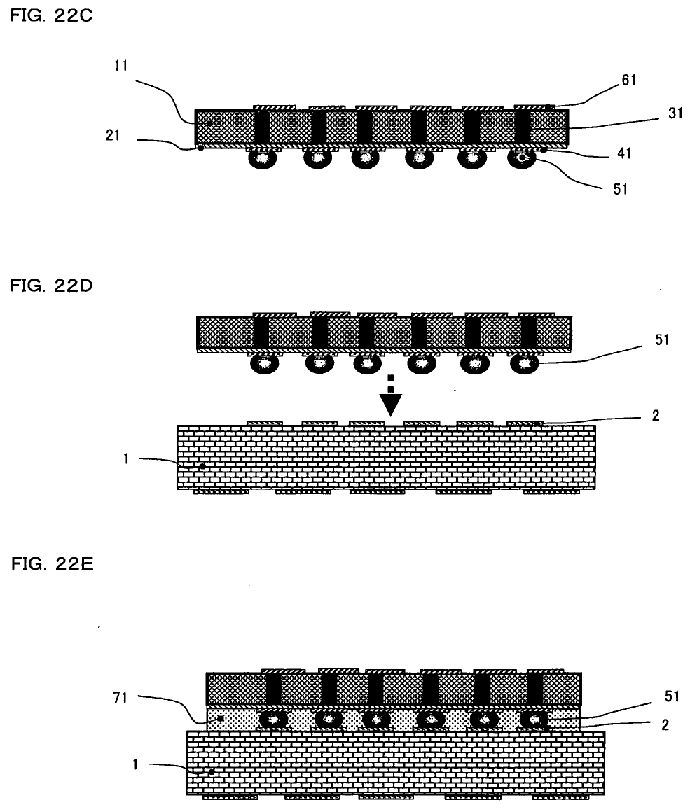

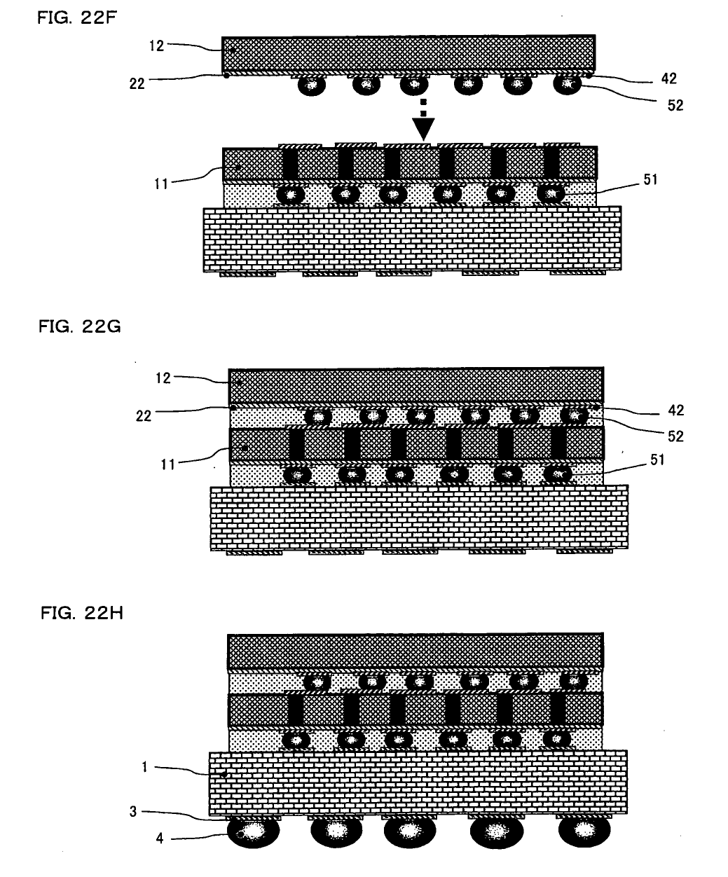

FIGS. 22A to 22H are diagrams illustrating a method of fabricating the semiconductor device according to a sixth embodiment of the present invention. FIGS. 22A to 22H show fabrication steps of the semiconductor device 100 shown in FIG. 1 according to the first embodiment of the present invention.

FIG. 22A is a diagram illustrating a wafer 10.

FIG. 22B is a diagram illustrating a cross section of the wafer 10. Bumps are formed on a surface of the wafer 10.

FIG. 22C is a diagram illustrating the first semiconductor chip 11 which is one of individual chips cut out from the wafer 10. The first circuit element surface 21 is formed on the top main surface of the first semiconductor chip 11. Then, the first through via 31 is formed for conducting electricity between the top main surface and the bottom surface of the first semiconductor chip 11. On the first circuit element surface 21, the first electrode pad 41 is disposed at a position where the first through via 31 is formed, and then the first bump 51 is formed on the first electrode pad 41. Furthermore, on the bottom surface of the first semiconductor chip 11, the first via pad 61 is arranged within a range from the position where the first through via 31 is formed to a portion where the second bump 52 is joined to the second semiconductor chip 12.

FIG. 22D is a diagram illustrating the mounting of the first semiconductor chip 11 to the interposer substrate 1. Each first bumps 51 formed on the first semiconductor chip 11 is connected to each substrate land 2 of the interposer substrate 1, thereby connecting the semiconductor chip to the interposer substrate 1 by using the flip-chip method.

FIG. 22E is a diagram illustrating a state where the first sealing resin 71 is formed between the first semiconductor chip 11 and the interposer substrate 1. The first sealing resin 71 is injected into a gap between the first semiconductor chip 11 and the interposer substrate 1 so as to be hardened, thereby improving the reliability of the portion in which the above two components are joined to each other.

FIG. 22F is a diagram illustrating the mounting of the second semiconductor chip 12 to the first semiconductor chip 11. Note that the second semiconductor chip 12 is created in the same manner as the first semiconductor chip 11 as described above. The second bump 52 formed on the second semiconductor chip 12 is connected to the first via pad 61 of the first semiconductor chip 11, thereby connecting the first semiconductor chip 11 to the second semiconductor chip 12 by using the flip-chip method.

FIG. 22G is a diagram illustrating a state where the second sealing resin 72 is formed between the first semiconductor chip 11 and the second semiconductor chip 12. The second sealing resin 72 is injected into a gap between the first semiconductor chip 11 and the second semiconductor chip 12 so as to be hardened, thereby improving the reliability of the portion in which the above two components are joined to each other.

FIG. 22H is a diagram illustrating a state where the solder balls 4 are formed on the soldering lands 3 disposed on the bottom surface of the interposer substrate 1.

Note that the present embodiment illustrates an example of a fabrication method of the semiconductor device 100 in which two semiconductor chips are stacked in layers. However, the same is true of the fabrication method of the semiconductor device in which semiconductor chips are stacked in layers of n (n is an integer greater than 2). In this case, bumps are formed on an i-th semiconductor chip (i is an integer greater than 2 and less than or equal to n).

### Seventh Embodiment

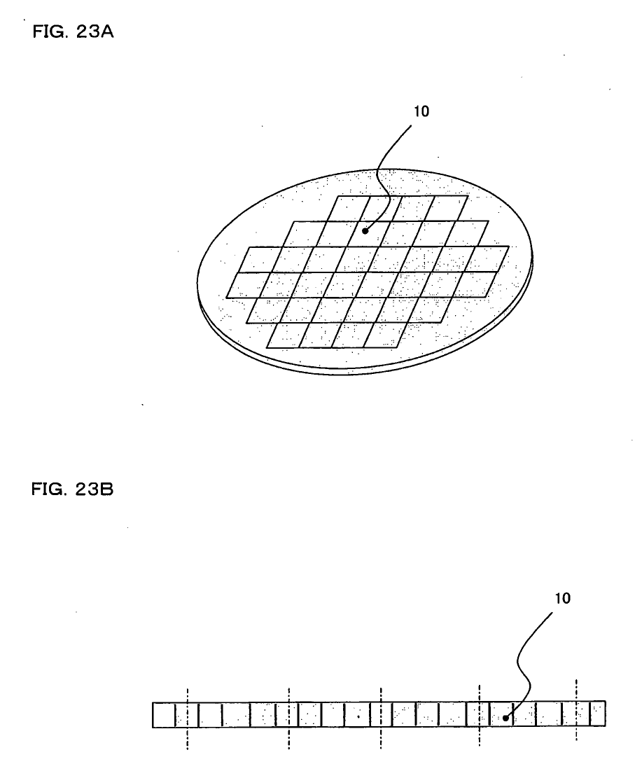

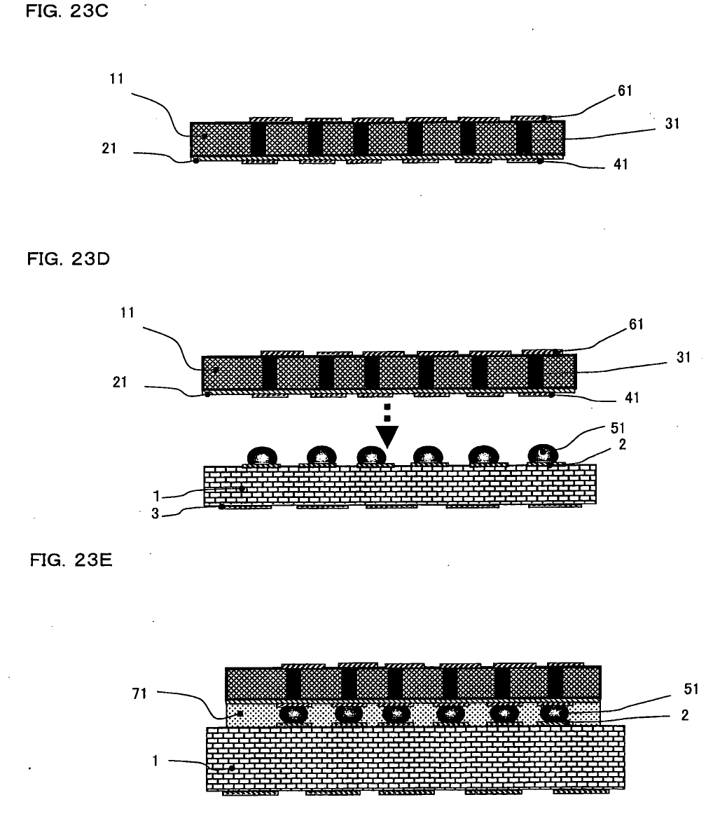

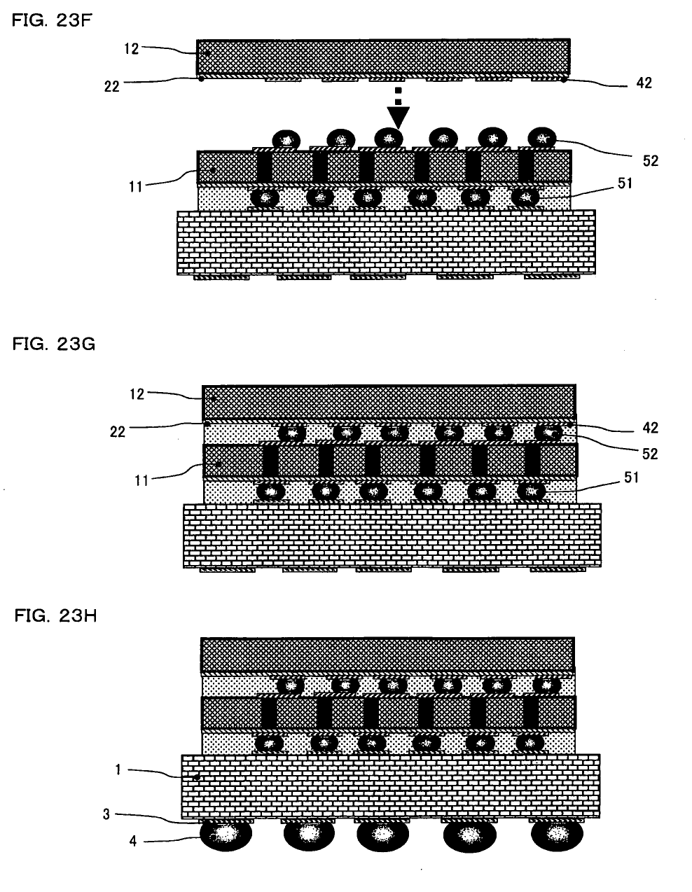

FIGS. 23A to 23I are diagrams illustrating a fabrication method of the semiconductor device according to a seventh embodiment of the present invention. FIGS. 23A to 23I show fabrication steps of the semiconductor device 100 shown in FIG. 1 according to the first embodiment of the present invention.

FIG. 23A is a diagram illustrating the wafer 10.

FIG. 23B is a diagram illustrating a cross section of the wafer 10. As shown in FIG. 22B, no bump is formed on the surface of the wafer 10.

FIG. 23C is a diagram illustrating the first semiconductor chip 11 which is one of individual chips cut out from the wafer 10. The first circuit element surface 21 is formed on the top main surface of the first semiconductor chip 11. Then, the first through via 31 is formed for conducting electricity between the top main surface and the bottom surface of the first semiconductor chip 11. On the first circuit element surface 21, the first electrode pad 41 is disposed at a position where the first through via 31 is formed. On the bottom surface of the first semiconductor chip 11, the first via pad 61 is arranged within a range from the position where the first through via 31 is formed to a portion where the second bump 52 is joined to the second semiconductor chip 12.

FIG. 23D is a diagram illustrating the mounting of the first semiconductor chip 11 to the interposer substrate 1. The first bump 51 for bonding the first semiconductor chip 11 to the interposer substrate 1 is formed on the substrate land 2 which is previously formed on the interposer substrate 1. The first bump 51 is connected to the first electrode pad 41 of the first semiconductor chip 11, thereby connecting the semiconductor chip to the interposer substrate 1 by using the flip-chip method.

FIG. 23E is a diagram illustrating a state where the first sealing resin 71 is formed between the first semiconductor chip 11 and the interposer substrate 1. The first sealing resin 71 is injected into a gap between the first semiconductor chip 11 and the interposer substrate 1 so as to be hardened, thereby improving the reliability of the portion in which the above two components are joined to each other.

FIG. 23F is a diagram illustrating the mounting of the second semiconductor chip 12 to the first semiconductor chip 11. Note that the second semiconductor chip 12 is created in the same manner as the first semiconductor chip 11 mentioned above. The second bump 52 for bonding the first semiconductor chip 11 to the second semiconductor chip 12 is formed on the first via pad 61 which is previously disposed on the bottom surface of the first semiconductor chip 11. The second bump 52 is connected to the second electrode pad 42 of the second semiconductor chip 12, thereby connecting the first semiconductor chip 11 to the second semiconductor chip 12 by using the flip-chip method.

FIG. 23G is a diagram illustrating a state where the second sealing resin 72 is formed between the first semiconductor chip 11 and the second semiconductor chip 12. The second sealing resin 72 is injected into a gap between the first semiconductor chip 11 and the second semiconductor chip 12 so as to be hardened, thereby improving the reliability of the portion in which the above two components are joined to each other.

FIG. 23H is a diagram illustrating a state where the solder balls 4 are formed on the soldering lands 3 disposed on the bottom surface of the interposer substrate 1.

Note that the present embodiment illustrates an example of a fabrication method of the semiconductor device 100 in which two semiconductor chips are stacked in layers. However, the same is true of the fabrication method of the semiconductor device in which semiconductor chips are stacked in layers of n (n is an integer greater than 2). In this case, bumps are formed on the bottom surface of an (i−1)th semiconductor chip (i is an integer greater than 2 and less than or equal to n).

### Eighth Embodiment

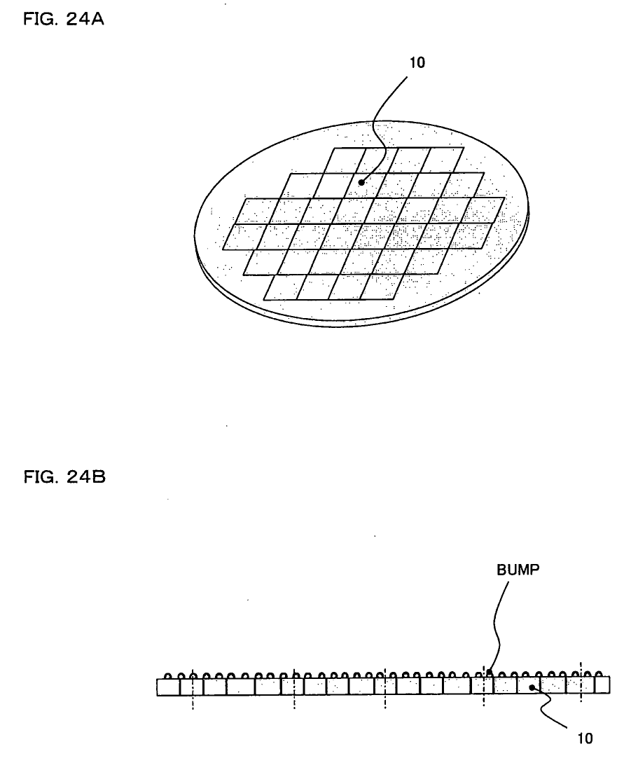

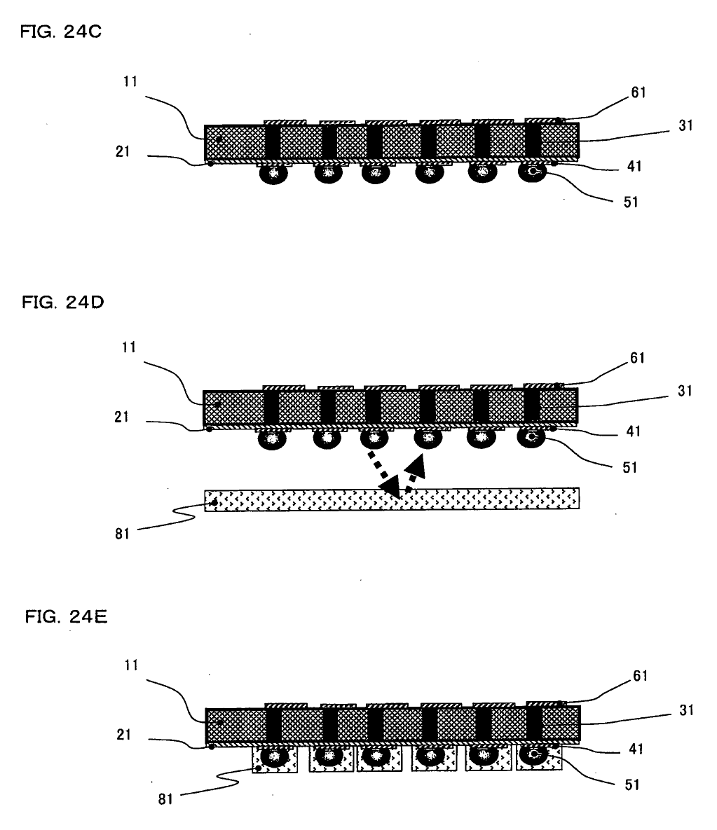

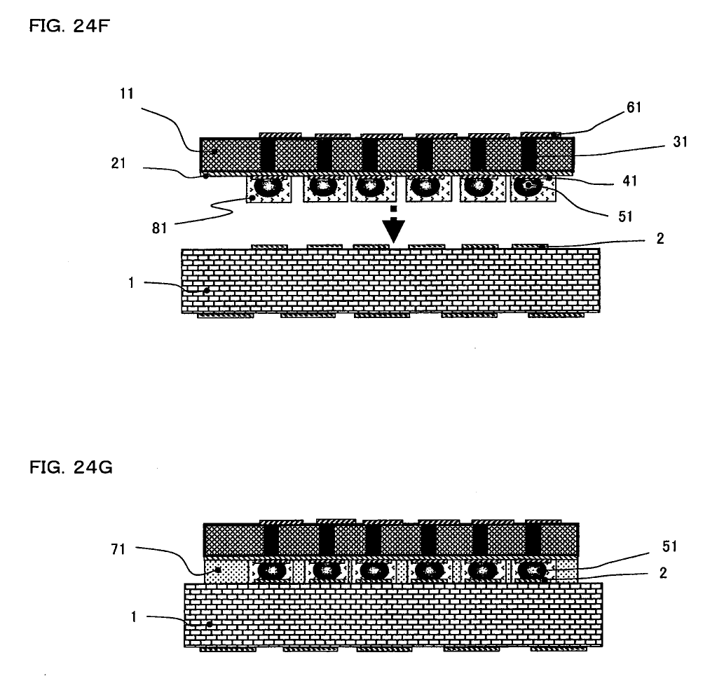

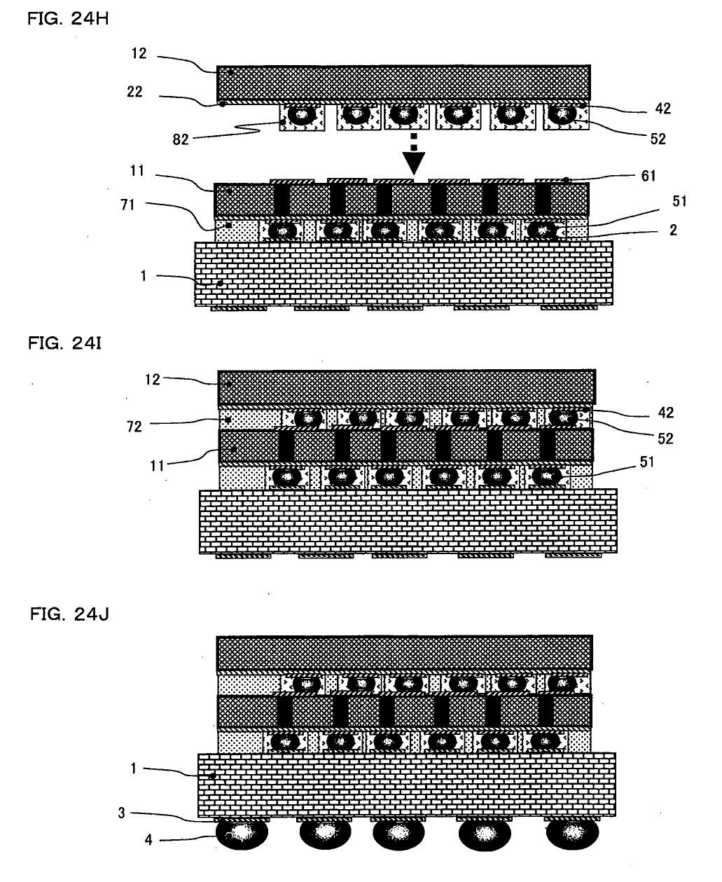

FIGS. 24A to 24J are diagrams illustrating a fabrication method of the semiconductor device according to an eighth embodiment of the present invention. FIGS. 24A to 24J show fabrication steps of a semiconductor device 300 shown in FIG. 11 according to the third embodiment of the present invention. For the sake of simplicity, a semiconductor device in which two semiconductor chips are stacked in layers will be described.

FIG. 24A is a diagram illustrating the wafer 10.

FIG. 24B is a diagram illustrating a cross section of the wafer 10. Bumps are formed on the surface of the wafer 10.

FIG. 24C is a diagram illustrating the first semiconductor chip 11 which is one of individual chips cut out from the wafer 10. The first circuit element surface 21 is formed on the top main surface of the first semiconductor chip 11. Then, the first through via 31 is formed for conducting electricity between the top main surface and the bottom surface of the first semiconductor chip 11. On the first circuit element surface 21, the first electrode pad 41 is arranged at a position at which the first through via 31 formed, and then the first bump 51 is formed on the first electrode pad 41. Furthermore, on the bottom surface of the first semiconductor chip 11, the first via pad 61 is arranged within a range from the position where the first through via 31 is formed to a portion where the second bump 52 is joined to the second semiconductor chip 12.

FIGS. 24D and 24E are diagrams illustrating a state where the first resin layer 81 is formed around the periphery of each first bump 51 of the first semiconductor chip 11. Note that a method of forming the first resin layer 81 will be more specifically described in a ninth embodiment to be described later.

FIG. 24F is a diagram illustrating the mounting of the first semiconductor chip 11 to the interposer substrate 1. Each first bump 51 of the first semiconductor chip 11 is connected to the substrate land 2 of the interposer substrate 1, thereby connecting the semiconductor chip to the interposer substrate 1 by using the flip-chip method.

FIG. 24G is a diagram illustrating a state where the first sealing resin 71 is formed between the first semiconductor chip 11 and the interposer substrate 1. The first sealing resin 71 is injected into a gap between the first semiconductor chip 11 and the interposer substrate 1, thereby improving the reliability of the portion in which the above two components are joined to each other.

FIG. 24H is a diagram illustrating the mounting of the second semiconductor chip 12 to the first semiconductor chip 11. Note that the second semiconductor chip 12 is created in a similar manner as the first semiconductor chip 11 mentioned above. The second bump 52 of the second semiconductor chip 12 is connected to the first via pad 61 of the first semiconductor chip 11, thereby connecting the first semiconductor chip 11 to the second semiconductor chip 12 by using the flip-chip method.

FIG. 24I is a diagram illustrating a state where the second sealing resin 72 is formed between the first semiconductor chip 11 and the second semiconductor chip 12. The second sealing resin 72 is injected into a gap between the first semiconductor chip 11 and the second semiconductor chip 12 so as to be hardened, thereby improving the reliability of the portion in which the above two components are joined to each other.

FIG. 24J is a diagram illustrating a state where the solder balls 4 are formed on the soldering land 3 disposed on the bottom surface of the interposer substrate 1.

### Ninth Embodiment

In the above eighth embodiment of the present invention, a resin layer has been described with reference to FIGS. 24D and 24E. Hereinafter, the present embodiment will describe the detailed method of forming the resin layer which has been described in the eighth embodiment.

### Example 1

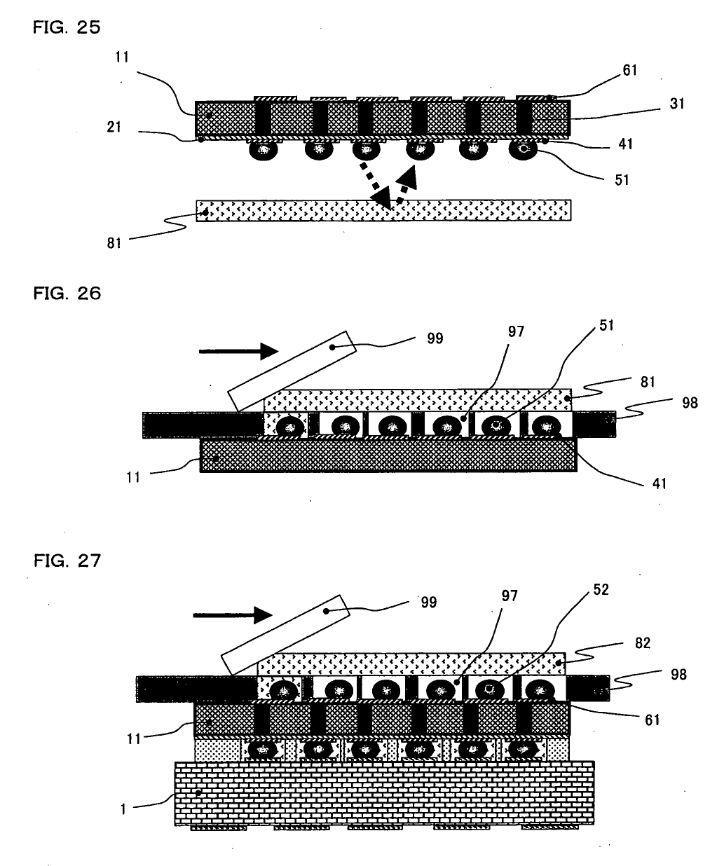

FIG. 25 is a diagram illustrating a transfer method. In FIG. 25, the first resin layer 81 is formed so as to have a predetermined thickness, before becoming hardened. Then, the first bumps 51 of the first semiconductor chip 11 are pressed against the first resin layer 81. As such, the first resin layer 81 is transferred and formed around the periphery of each of the first bumps 51. Thereafter, the first resin layer 81 is hardened by applying the heat.

### Example 2

FIG. 26 is a diagram illustrating a screen printing method. In FIG. 26, the first resin layer 81 is formed on a top surface of a mask 98 having mask apertures 97, before becoming hardened. The mask 98 is pressed against the top main surface, of the first semiconductor chip 11, on which the first bump 51 is formed. Each mask aperture 97 is placed at a position of each first bump 51 formed on the top main surface of the first semiconductor chip 11, and then the first resin layer 81 before becoming hardened is squeezed to the mask aperture 97 by using a squeegee 99. Thus, the first resin layer 81 is transferred and then formed around the periphery of each first bump 51. Thereafter, the first resin layer 81 may be hardened by applying the heat.

### Example 3

FIG. 27 is a diagram illustrating a screen printing method. In an example 3, a method of forming the second resin layer 82 around the periphery of each second bump 52 will be described. In FIG. 27, the first via pad 61 is arranged on the bottom surface of the first semiconductor chip 11 which is connected to the interposer substrate 1 by using a flip-chip method, and then the second bump 52 is formed on the first via pad 61. Similarly to the example 2 mentioned above, each mask aperture 97 is placed at a position of each second bump 52, and then the second resin layer 82 formed on the mask 98 is squeezed to the mask aperture 97 by using a squeegee 99 before the second resin layer 82 is hardened. Thus, the second resin layer 82 is transferred and then formed around the second bump 52. Thereafter, the second resin layer 82 may be hardened by applying the heat.

As described above, in the above-described method of forming the resin layer, the resin layer can be formed around the peripheries of multiple bumps in a collective manner.

By forming the solder balls 4 on the bottom surface of the interposer substrate, the external electrode forms a Ball Grid Array (BGA). However, a Land Grid Array may be formed only by using the soldering lands with no solder balls.

Note that in the semiconductor device of the first to ninth embodiments of the present invention, two or four semiconductor chips are stacked in layers. The number of the semiconductor chips to be stacked is not limited thereto. It is understood that the same effect can be obtained as long as a semiconductor device has a structure in which semiconductor chips are stacked in multi-layers. Furthermore, even if the interposer substrate is not used in a semiconductor device such as a lead frame type QFP, the same effect can be obtained.

While the invention has been described in detail, the foregoing description is in all aspects illustrative and not restrictive. It is understood that numerous other modifications and variations can be devised without departing from the scope of the invention.

What is claimed is:

1. A semiconductor device in which at least n (n is an integer greater than or equal to 2) semiconductor chips, which are connected to each other via bumps, are arranged in a stacked layer structure of n layers, and each gap between the semiconductor chips is sealed with sealing resin, wherein
an i-th (i is an integer from 1 to n−1) semiconductor chip includes:
through vias extending through a top main surface of the i-th semiconductor chip to a bottom surface opposite to the top main surface;
a circuit element surface formed on the top main surface;
pads arranged on the circuit element surface;
bumps respectively formed on the pads; and
via pads, to which the bumps of an (i+1)th semiconductor chip are respectively joined, which are disposed on the bottom surface of the i-th semiconductor chip, and
an n-th semiconductor chip includes:
a circuit element surface formed on a top main surface of the n-th semiconductor chip;
pads arranged on the circuit element surface; and
bumps respectively formed on the pads, and
each of the bumps of the i-th semiconductor chip is arranged at a position different from a position at which each of the bumps of the (i+1)th semiconductor chip is arranged.

2. The semiconductor device according to claim 1, wherein
the bumps are arranged on a top main surface of each of the semiconductor chips, and
each of the bumps of the (i+1)th semiconductor chip is electrically connected to any of the bumps of the i-th semiconductor chip through each of the through vias.

3. The semiconductor device according to claim 1, wherein
the bumps are arranged in a matrix so as to be spaced at regular intervals on an entirety of the top main surface of each of the semiconductor chips, and
each of the bumps of the (i+1)th semiconductor chip is at least arranged at a position extending vertically upward from a position of gravity center of a minimum rectangle formed by four bumps among the bumps of the i-th semiconductor chip.

4. The semiconductor device according to claim 1, wherein
a same number of bumps are arranged on each of the semiconductor chips.

5. The semiconductor device according to claim 1, wherein
the bumps are arranged along the periphery of only two edges of each of the semiconductor chips.

6. The semiconductor device according to claim 1, wherein
the bumps are arranged along the periphery of all four edges of each of the semiconductor chips.

7. The semiconductor device according to claim 1, wherein
the bumps are made of metal.

8. The semiconductor device according to claim 7, wherein
the bumps are solder balls.

9. The semiconductor device according to claim 7, wherein
the bumps are gold electrodes.

10. The semiconductor device according to claim 1, wherein
a thickness of each of the semiconductor chips is from 0.01 mm to 0.15 mm.

11. The semiconductor device according to claim 1, wherein
each of the bumps is formed on the circuit element surface and arranged at a position at which each of the through vias is formed.

12. The semiconductor device according to claim 1, wherein
each of the bumps is formed on the circuit element surface and arranged at a position shifted from a position at which the each of the through vias is formed.

13. The semiconductor device according to claim 1, wherein
the periphery of each of the bumps is covered with a resin layer different from the sealing resin.

14. The semiconductor device according to claim 13, wherein
a curing shrinkage rate of the resin layer covering the periphery of each of the bumps is lower than that of the sealing resin.

15. The semiconductor device according to claim 13, wherein
a thermal expansion coefficient of the resin layer covering the periphery of each of the bumps is lower than that of the sealing resin.

16. The semiconductor device according to claim 1, further comprising an interposer substrate, which includes an external power source terminal, disposed below the semiconductor chips arranged in a stacked layer of n layers, wherein
each of the bumps of the first semiconductor chip is joined to a substrate land formed on the interposer substrate.

17. The semiconductor device according to claim 16, wherein
at least one of the semiconductor chips stacked on the interposer substrate is connected to the interposer substrate by a conductive wire.

18. The semiconductor device according to claim 16, wherein
the n-th semiconductor chip is connected to the interposer substrate by a conductive wire.

19. A fabrication method of a semiconductor device in which at least n (n is an integer greater than or equal to 2) semiconductor chips, which are connected to each other via bumps, are arranged in a stacked layer structure of n layers, and each gap between the semiconductor chips is sealed with sealing resin, the fabrication method comprising the steps of:
stacking i (i is an integer from 1 to n−1) semiconductor chips successively from a first layer; and
stacking thereon an n-th semiconductor chip, wherein
the step of stacking an i-th semiconductor chip includes the steps of:
forming through vias extending through a top main surface of the i-th semiconductor chip to a bottom surface opposite to the top main surface;
forming a circuit element surface on the top main surface of the i-th semiconductor chip;
arranging pads on the circuit element surface;
forming bumps on the pads, respectively,
disposing via pads, to which the bumps of an (i+1)th semiconductor chip are respectively joined, on the bottom surface of the i-th semiconductor chip,
stacking the i-th semiconductor chip on the semiconductor device in which the semiconductor chips are arranged in a stacked layer structure of (i−1) layers; and
filling a portion in which the i-th semiconductor chip is joined to the (i−1)th semiconductor chip with the sealing resin, and
the step of further stacking the n-th semiconductor chip includes the steps of:
forming a circuit element surface on a top main surface of the n-th semiconductor chip;
arranging pads on the circuit element surface; and
forming the bumps on the pads, respectively,
stacking the n-th semiconductor chip on the semiconductor device in which the semiconductor chips are arranged in a stacked layer structure of (n−1) layers; and
filling a portion in which the n-th semiconductor chip is joined to an (n−1)th semiconductor chip with the sealing resin, and
each of the bumps of the i-th semiconductor chip is arranged at a position different from a position at which each of the bumps of an (i+1)th semiconductor chip is arranged.

20. A fabrication method of a semiconductor device in which at least n (n is an integer greater than or equal to 2) semiconductor chips, which are connected to each other via bumps, are arranged in a stacked layer structure of n layers, and each gap between the semiconductor chips is sealed with sealing resin, the fabrication method comprising the steps of:
stacking i (i is an integer from 1 to n−1) semiconductor chips successively from a first layer; and
stacking thereon an n-th semiconductor chip, wherein
the step of stacking an i-th semiconductor chip includes the steps of:
forming through vias extending through a top main surface of the i-th semiconductor chip to a bottom surface opposite to the top main surface;
forming a circuit element surface on the top main surface of the i-th semiconductor chip;
arranging pads on the circuit element surface;
arranging via pads on the bottom surface of the i-th semiconductor chip;
stacking the i-th semiconductor chip on the semiconductor device in which the semiconductor chips are arranged in a stacked layer structure of (i−1) layers;
filling a portion in which the i-th semiconductor chip is joined to the (i−1)th semiconductor chip with the sealing resin;
forming bumps of the (i+1)th semiconductor chip on the via pads formed on the circuit element surface of the i-th semiconductor chip; and
arranging via pads to which the bumps of the (i+1) th semiconductor chip are respectively joined, and
the step of stacking the n-th semiconductor chip includes the steps of:
forming a circuit element surface on a top main surface of the n-th semiconductor chip;
arranging pads on the circuit element surface;
stacking the n-th semiconductor chip on the semiconductor device in which the semiconductor chips are arranged in a stacked layer structure of (n−1) layers; and
filling a portion in which the n-th semiconductor chip is joined to an (n−1)th semiconductor chip with the sealing resin, and
each of the bumps of the i-th semiconductor chip is arranged at a position different from a position at which each of the bumps of the (i+1)th semiconductor chip is arranged.
